(19) United States
(12) Patent Application Publication
(10) Pub. No.: US 2004/0033435 A1
(43) Pub. Date: Feb. 19, 2004

(54) Process for producing printing plate precursor

(75) Inventors: Hideo Miyake, Shizuoka (JP); Akio Oda, Shizuoka (JP)

Correspondence Address: SUGHRUE MION, PLLC, 2100 PENNSYLVANIA AVENUE, N.W., WASHINGTON, DC, 20037, US

(73) Assignee: FUJI PHOTO FILM CO., LTD.

(21) Appl. No.: 10/372,242

(22) Filed: Feb. 25, 2003

(30) Foreign Application Priority Data
Feb. 26, 2002 (JP) P. 2002-049707

(51) Int. Cl. B05D 1/36; G03F 7/16; G03F 7/00; B41C 1/055

(52) U.S. Cl. 430/270.1; 427/555; 427/407.1

(57) ABSTRACT

The invention provides a process for the preparation of an infrared laser positive-working printing plate precursor for direct plate-making excellent in scratch resistance and discrimination between image area and non-image area, particularly in press life, which can make a printing plate directly from digital signal, particularly from computer, in which the process is provided for the preparation of a multi-layer printing plate precursor comprising a support, an underlayer and an image-recording layer, in this order, in which the underlayer comprises a water-insoluble and alkali-soluble resin, the image-recording layer comprises a water-insoluble and alkali-soluble resin and an infrared absorbent, and the image-recording layer increases the solubility in an alkaline aqueous solution upon irradiation with infrared laser beam, wherein the process comprises forming the image-recording layer with the use of a solvent that doesn't dissolve a component of the underlayer in an amount of 20% by weight or more as a solvent for image-recording layer coating solution

### FIELD OF THE INVENTION

The present invention relates to a process for the preparation of a printing plate precursor and more particularly to a process for the preparation of a so-called direct plate making printing plate precursor excellent in scratch resistance and development latitude, particularly in press life, which can make a printing plate directly from digital signal from computer, etc.

### BACKGROUND OF THE INVENTION

The recent development of laser is so remarkable that high output and small-sized solid lasers and semiconductor lasers emitting light having a wavelength ranging from near infrared to infrared have been easily available. As exposing light sources for use in the direct plate-making from digital data outputted from computer, etc., these lasers are very useful.

This direct plate-making infrared laser positive-working printing plate comprises a binder resin soluble in an alkaline aqueous solution and an infrared absorbent or the like which absorbs light to generate heat (hereinafter occasionally referred to as “IR dye”) as essential components. The IR dye or the like acts as a dissolution inhibitor for interacting with the binder resin to substantially lower the solubility of the binder resin on the unexposed area (image area). On the exposed area (non-image area), the heat thus generated weakens the interaction between the IR dye or the like and the binder resin, causing the binder resin to be dissolved in an alkaline developer. In this manner, a lithographic printing plate having an image area imagewise distributed thereon is formed.

However, such an infrared laser positive-working printing plate precursor leaves something to be desired in the difference between the dissolution resistance of unexposed area (image area) to developer and the solubility of exposed area (non-image area) under various working conditions and thus Is disadvantageous in that overdevelopment (elution of image area causing film reduction phenomenon involving the reduction of the thickness of the image layer) or under development (film remaining phenomenon that the non-image area is partially left undissolved) can easily occur under various working conditions. Further, such an infrared laser positive-working printing plate precursor is subject to variation of surface conditions because the image layer has so low a strength that it can be minutely scratched when touched during handling. Also when such a minute scratch or slight variation of surface conditions occurs, the solubility rises in the vicinity of the scratched or otherwise affected area. Thus, the unexposed area (image area) in the vicinity of the scratched or other affected area is dissolved to form marks, causing the deterioration of press life or affinity.

This problem is derived from the essential different in plate making mechanism between infrared laser positive-working printing plate material and positive-working printing plate material adapted for plate making by UV exposure. In other words, the positive-working printing plate material adapted for plate making by UV exposure comprises a binder resin soluble in an alkaline aqueous solution, onium salts and quinonediazide compounds as essential components. These onium salts or quinonediazide compounds play two roles. In other words, they not only interact with the binder resin to act as a dissolution inhibitor on the unexposed area (image area) but also decompose by light to generate an acid that acts as a dissolution accelerator on the exposed area (non-image area).

On the contrary, the IR dye or the like in the infrared laser positive-working printing plate material acts only as a dissolution inhibitor for unexposed area (image area) and thus doesn't accelerate the dissolution of exposed area (non-image area). Accordingly, the infrared laser positive-working printing plate material is disadvantageous in that when as a binder resin there is used one having a high solubility in an alkaline developer to make difference in solubility between unexposed area and exposed area, it causes film reduction, deteriorates scratch resistance or labilizes the undeveloped state of the infrared laser positive-working printing plate material. On the other hand, when the solubility of the binder resin is lowered to strengthen the unexposed area, the sensitivity of the infrared laser positive-working printing plate material is lowered. Accordingly, the range of development conditions with which the desired discrimination between image area and non-image area can be maintained (development latitude) is restricted.

Therefore, various studies have been made of development of selective dissolution inhibitor which eliminates dissolution inhibition on the exposed area but maintains dissolution inhibition on the unexposed area. Japanese Patent Laid-Open No. 1995-285275, etc. disclose a technique which comprises incorporating a photo-heat converting agent and a material which is heat-decomposable and substantially lowers the solubility of an alkali-soluble resin when it stays undecomposed in the recording layer of infrared laser positive-working printing plate material so that the dissolution of the recording layer can be inhibited to enhance the scratch resistance thereof while on the exposed area, the material decomposes by heat generated by the heat-photo-heat converting agent to lose its effect of inhibiting the dissolution of the alkali-soluble resin, making it possible to enhance the sensitivity of the infrared laser positive-working printing plate material.

However, the incorporation of these compounds have some effects of accelerating dissolution and enhancing discrimination and physical properties and sensitivity of film, which cannot be considered sufficient. However, this approach leaves something to be desired in the improvement of press life. Thus, further improvement of press life is needed.

### SUMMARY OF THE INVENTION

It is therefore an aim of the invention to provide a method for obtaining a printing plate precursor which exhibits an enhanced discrimination in development, i.e., discrimination between image area and non-image area and an improved scratch resistance, particularly a sufficiently improved press life, by overcoming the aforementioned conventional technical disadvantages of so-called direct plate-making printing plate precursor which can make a printing plate directly from digital signal from computer, etc.

In the light of the fact that the aforementioned problems with scratch resistance and discrimination in development have never been sufficiently solved despite studies from the standpoint of material to be used, the inventors paid their attention to and made extensive studies of conditions of production of printing plate precursor. As a result, it was found that the properties of the solvent for the image-recording layer coating solution to be used in the provision of the image-recording layer have a great effect on the mechanical properties, particularly press life, of the image layer. Further studies were made on the basis of this discovery. The invention has thus been worked out. The essence of the invention lies in the following constitution.

(1) A process for producing a multi-layer printing plate precursor, the multi-layer printing plate precursor comprising a support, an underlayer and an image-recording layer, in this order, in which the underlayer comprises a water-insoluble and alkali-soluble resin, the image-recording layer comprises a water-insoluble and alkali-soluble resin and an infrared absorbent, and the image-recording layer increases the solubility in an alkaline aqueous solution upon irradiation with infrared laser beam,

wherein the process comprises forming the image-recording layer with the use of a solvent that doesn't dissolve a component of the underlayer in an amount of 20% by weight or more as a solvent for image-recording layer coating solution.

(2) The process for producing a multi-layer printing plate precursor as described in the (1), wherein the solvent for image-recording layer coating solution is a solvent that doesn't dissolve a component of the underlayer in an amount of 13% by weight or more.

(3) The process for producing a multi-layer printing plate precursor as described in the (1), wherein the solvent for image-recording layer coating solution is a solvent that doesn't dissolve a component of the underlayer in an amount of 10% by weight or more.

(4) The process for producing a multi-layer printing plate precursor as described in the (1), wherein the solvent for image-recording layer coating solution is at least one solvent selected from the group consisting of ethylene dichloride, cyclohexanone, methyl ethyl ketone, methanol, ethanol, propanol, ethylene glycol monomethyl ether, 1-methoxy-2-propanol, 2-methoxy ethyl acetate, 1-methoxy-2-propyl acetate, dimethoxyethane, methyl lactate, ethyl lactate, N,N-dimethylacetamide, N,N-dimethylformamide, tetramethylurea, N-methylpyrrolidone, dimethyl sulfoxide, sulfolane, γ-butyrolactone and toluene.

(5) The process for producing a multi-layer printing plate precursor as described in the (1), wherein the solvent for image-recording layer coating solution is at least one solvent selected from the group consisting of cyclohexanone, methyl ethyl ketone, methanol, ethanol, propanol and 1-methoxy-2-propanol.

(6) The process for producing a multi-layer printing plate precursor as described in the (1), comprises:

coating a underlayer coating solution on the support; and

coating the image-recording layer solution on the under layer.

(7) The process for producing a multi-layer printing plate precursor as described in the (1), comprises:

coating a underlayer coating solution on the support;

drying the coated underlayer; and

coating the image-recording layer solution on the under layer.

(8) The process for producing a multi-layer printing plate precursor as described in the (1), wherein the a water-insoluble and alkali-soluble resin in the underlayer includes at least one of a water-insoluble and alkali-soluble polymer having a sulfonamide group and a water-insoluble and alkali-soluble polymer having an active imide group.

(9) The process for producing a multi-layer printing plate precursor as described in the (1), wherein the image-recording layer further comprises a heat-decomposable material that, when thermally undecomposed, substantially lowers the solubility of the water-insoluble and alkali-soluble resin.

(10) The process for producing a multi-layer printing plate precursor as described in the (9), wherein the heat-decomposable material is an onium salt.

(11) The process for producing a multi-layer printing plate precursor as described in the (10), wherein the onium salt is a diazonium salt.

The application of a printing plate precursor having a multi-layer structure normally involves application of underlayer coating solution, and subsequent application of upper layer coating solution, optionally preceded by the drying of the underlayer; In the invention, by using a solvent which doesn't dissolve a component of the underlayer (lower layer) in an amount of not greater than 20% by weight as a solvent for image-recording layer coating solution to be used in the formation of an upper layer, i.e., image-recording layer, i.e., by inhibiting the mixing of the underlayer component with the image-recording layer, the solubility of the image area during the development of the resulting printing plate precursor decreases (less film reduction) and the dissolution of the non-image area an be accelerated (less film remaining), resulting in the expansion of development latitude and rendering the printing plate precursor less scratchable. In particular, press life can be remarkably enhanced.

The mechanism that the selection of the solvent for image-recording layer coating solution in the production of the aforementioned printing plate precursor exerts an unexpected remarkable effect on the scratch resistance and development latitude, particularly press life, of printing plate precursor is not definite but can be presumed as follows. In other words, a printing plate precursor having a multi-layer structure is normally designed such that the underlayer can be easily dissolved and the upper layer can be less dissolved than the underlayer from the standpoint of capability of securing discrimination in development. To this end, the underlayer normally contains a component capable of accelerating dissolution. It is thought that when this component capable of accelerating dissolution is eluted with the upper layer during the application of the upper layer coating: solution, this component raises the solubility of the upper layer to accelerate the penetration of the developer from the upper layer, raising the effect of the developer on the photosensitive layer (particularly in the vicinity of the support). The resulting drop of the adhesion of the photosensitive layer to the support leads to deterioration of press life. Accordingly, when as the solvent for upper layer coating solution there is used a solvent which can difficultly dissolve the underlayer component such as the aforementioned component capable of accelerating dissolution therein as in the invention, the elution of the aforementioned component capable of accelerating dissolution with the upper layer can be inhibited, making the photosensitive layer less subject to effect of developer. As a result, the deterioration of press life can be inhibited, making it possible to remarkably enhance press life more than ever.

The elution of the underlayer component such as the aforementioned component capable of accelerating dissolution with the upper layer not only causes the deterioration of press life but also weakens the development resistance (resist) of the upper layer, deteriorating development latitude or scratch resistance. However, by properly selecting the solvent for upper layer coating solution to inhibit the elution of the underlayer component such as component capable of accelerating dissolution with the upper layer as in the invention, the development resistance, development latitude and scratch resistance of the upper layer can be enhanced.

Further, in the case where the application of the upper layer coating solution is continuously effected over an extended period of time in the prolonged continuous production of printing plate precursor, if the elution of the underlayer component with the upper layer coating solution can be inhibited, the change of the composition of the upper layer coating solution can be inhibited over an extended period of time, making it possible to continuously produce a printing plate precursor invariably over an extended period of time.

### BRIEF DESCRIPTION OF THE DRAWINGS

By way of example and to make the description more clear, reference is made to the accompanying drawing in which:

FIG. 1 is a schematic diagram illustrating the coating/drying step in an embodiment of the process for the preparation of the printing plate precursor of the invention, wherein the sign P indicates a support, the sign P′ indicates a printing plate precursor, the reference numeral 1 indicates an underlayer coating/drying zone, the reference numeral 2 indicates an image-recording layer coating/drying zone, the reference numeral 12 indicates an underlayer coating device, the reference numeral 13 indicates an underlayer coating solution, the reference numeral 14 indicates a coating roller, the reference numeral 15 indicates an underlayer coating device, the reference numeral 16 indicates a first drying section, the reference numeral 17 indicates a second drying section, the reference numeral 18 indicates a third drying section, the reference numeral 19 indicates a cooling section, the reference numeral 17 indicates a second drying section, the reference numeral 22 indicates a upper layer coating device, the reference numeral 23 indicates a upper layer coating solution, the reference numeral 24 indicates a coating roller, the reference numeral 25 indicates a upper layer drying device, the reference numeral 26 indicates a fourth drying section, the reference numeral 27 indicates a fifth drying section, the reference numeral 28 indicates a sixth drying section, the reference numeral 29 indicates a cooling section, the signs a, a′, c and c′ each indicate an air Inlet, and the signs b, b′, d and d′ each indicate an air outlet.

### DETAILED DESCRIPTION OF THE INVENTION

The invention will be further described hereinafter.

The essence of the invention lies in a process for the preparation of a multi-layer printing plate precursor comprising a support having an underlayer containing a water-insoluble and alkali-soluble resin and an image-recording layer containing a water-insoluble and alkali-soluble resin and an infrared absorbent provided thereon, which image-recording layer showing an increase of solubility in an alkaline aqueous solution when exposed to infrared laser beam, wherein as a solvent for image-recording layer coating solution to be used in the formation of the image-recording layer there is used a solvent which doesn't dissolve the component of the underlayer in an amount of not lower than 20% by weight.

The multi-layer printing plate precursor to which the preparation process of the invention is applied will be described hereinafter. The process for the preparation of the multi-layer printing plate precursor will be then described.

[Alkali-Soluble Resin]

The alkali-soluble resin (polymer compound) to be incorporated in the image-recording layer and the underlayer of the printing plate precursor to be used in the invention will be described hereinafter.

The image-recording layer of the printing plate precursor to be used in the invention comprises a polymer compound insoluble in water but soluble in an alkaline aqueous solution(hereinafter occasionally referred to as “alkali-soluble polymer or alkali-soluble resin”) incorporated therein. The term “alkali-soluble polymer” as used herein is meant to include a homopolymer containing an acidic group in the main chain and/or side chains in a polymer, copolymer thereof and mixture thereof. Accordingly, the image-recording layer according to the invention is dissolved when it comes in contact with an alkaline developer.

The alkali-soluble polymer employable herein is not specifically limited so far as it is known. In practice, however, the alkali-soluble polymer is preferably a polymer compound containing any functional group selected from the group consisting of (1) phenolic hydroxyl groups, (2) sulfonmide groups and(3) active imide groups in its molecule. For example, the following compounds may be exemplified, but the invention is not limited thereto.

(1) Examples of the polymer compound having a phenolic hydroxyl group include novolak resins such as phenol formaldehyde resin, m-cresol formaldehyde resin, p-cresol formaldehyde resin, m-/p-mixed credol formaldehyde resin, phenol/cresol (a-, p- or m-/p-mixed) mixed formaldehyde resin and xylenol formaldehyde resin, and pyrogallol acetone resin. Other preferred examples of the polymer compound containing a phenolic hydroxyl group employable herein include polymer compounds having a phenolic hydroxyl group in its side chain. Examples of the polymer compound having a phenolic hydroxyl group in its side chain include polymer compounds obtained by the homopolymerization of polymerizable monomers made of low molecular compounds each having one unsaturated bond polymerisable with phenolic hydroxyl group or the copolymerization thereof with other polymerizable monomers.

Preferred examples of the polymerizable monomer containing a phenolic hydroxyl group employable herein include include acrylamide, methacrylamide, acrylic acid ester, methacrylic acid ester and hydroxystyrene containing a phenolic hydroxyl group. Specific examples of these compounds include N-(2-hydroxyphenyl) acrylamide, N-(3-hydroxyphenyl) acrylamide, N-(4-hydroxyphenyl)arylanide, N-(2-hydroxyphenyl) methacrylamide, N-(3-hydroxyphenyl)methacrylamide, N-(4-hydroxyphenyl) methacrylamide, o-hydroxyphenyl acrylate, m-hydroxyphenyl methacrylate, p-hydroxyphenyl methacrylate, o-hydroxystyrene, m-hydroxystyrene, p-hydroxystyrene, 2-(2-hydroxyphenyl) ethylacrylate, 2-(3-hydroxyphenyl)ethylacrylate, 2-(4-hydroxyphenyl)ethylacrylate, 2-(2-hydroxyphenyl) ethylmethacrylate, 2-(3-hydroxyphenyl)ethylmethacrylate, and 2-(4-hydroxyphenyl) ethylmethacrylate. Two or more such resins containing a phenolic hydroxyl group may be used in combination. An described in U.S. Pat. No. 4,123,279, polycondensates of phenol with formaldehyde having a C3-C8 alkyl group as a substituent, such as t-butylphenol formaldehyde resin and octylphenol formaldehyde resin may be used in combination with these compounds.

(2) Examples of the alkali-soluble polymer compound containing a sulfonamide group include polymer compounds obtained by the homopolymerization of polymerizable monomers having a sulfonamide group or the copolymerization thereof with other polymerisable monomers. Examples of the polymerizable monomer having a sulfonamide group include polymerizable monomers made of a low molecular compound having a sulfonamide group —NH—SO₂— having at least one hydrogen atom bonded to the nitrogen atom and a polymerizable unsaturated bond per molecule. Preferred among these polymerizable monomers are low molecular compounds containing acryloyl group, allyl group or vinyloxy group and substituted or mono-substituted amino sulfonyl group or substituted sulfonylimino group.

(3) As the alkali-soluble polymer compound containing an active imide group there is preferably used one containing an active imide group in its molecule. Examples of such a polymer compound include polymer compounds obtained by the homopolymerization of polymerizable monomers made of a low molecular compound having an active imide group and a polymerizable unsaturated bond per molecule or the copolymerization thereof with other polymerizable monomers.

Specific examples of such a compound employable herein include N-(p-toluenesulfonyl)methaetylamide, and N-(p-toluenesulfonyl) acrylamide.

Alternatively, as the alkali-soluble polymer compound there is preferably used a polymer compound obtained by the polymerization of two or more of the aforementioned polymerizable monomer having a phenolic hydroxyl group, polymerizable monomer having a sulfonamide group and polymerizable monomer having an active imide group or a polymer compound obtained by the copolymerization of two or more of these polymerizable monomers with other polymerizable monomers. In the case where a polymerizable monomer having a phenolic hydroxyl group is copolymerized with a polymerizable monomer having a sulfonmide group and/or a polymerizable monomer having an active imide group, the mixing ratio of these components by weight is preferably from 50:50 to 5:95, particularly from 40:60 to 10:90.

When the alkali-soluble polymer in the printing plate precursor to be used in the invention is a copolymer of the aforementioned polymerizable monomer having a phenolic hydroxyl group, polymerizable monomer having a sulfonamide group or polymerizable monomer having an active imide group with other polymerizable monomers, the content of a monomer providing alkali solubility is preferably not lower than 10 mol-%, more preferably not lower than 20 mol-%. When the content of the monomer providing alkali solubility is less than 10 mol-%, the resulting alkali solubility can be insufficient, occasionally making it impossible to sufficiently attain the effect of improving the development latitude.

As the other monomer components copolymerizable with the aforementioned polymerizable monomer having a phenolic hydroxyl group, polymerizable monomer having a sulfonamide group or polymerizable monomer having: an active imide group there can be exemplified the following compounds (m1) to (m12), but the invention is not limited thereto.

Examples of the copolymerization method for the production of the polymer compound soluble in an aqueous alkali include graft copolymerization method, block copolymerization method and random copolymerization method, which have heretofore been known.

(m1) Acrylic acid esters and methacrylic acid esters having aliphatic hydroxyl group such as 2-hydroxyethyl acrylate and 2-hydroxyethyl methacrylate;

(m2) Alkyl acrylates such as methyl acrylate, ethyl acrylate, propyl acrylate, butyl acrylate, amyl acrylate, hezyl acrylate, octyl acrylate, benzyl acrylate, 2-chloroethyl acrylate and glycidyl acrylate;

(m3) Alkyl methacrylates such as methyl methacrylate, ethyl mathacrylate, propyl methacrylate, butyl methacrylate, amylme thacrylate, hexylimethacrylate, cyclohexylmethacrylate, benzyl methacrylate, 2-chloroethyl aethacrylate and glycidyl methacrylate;

(m4) Acrylamides or methacrylamides such as acrylamide, methacrylaide, Nrmethylol acrylamide, N-ethyl acrylamide, N-hexyl methacrylamide, H-cyclohexyl acrylamide, N-hydroxyethyl acrylamide, N-phenyl acrylamide, N-nitrophenyl acrylamide and N-ethyl-N-phenyl acrylanide;

(m5) Vinyl ethers such as ethyl vinyl ether., 2-chloroethyl vinyl ether, hydroxyethyl vinyl ether, propyl vinyl ether, butyl vinyl ether, octyl vinyl ether and phenyl vinyl ether;

(m6) Vinyl esters such as vinyl acetate, vinyl chloroacetate, vinyl butyrate and vinyl benzoate;

(m7) Styrenes such as styrene, α-methyl styrene and chloromethyl styrene;

(m8) Vinyl ketones such as methyl vinyl ketone, ethyl vinyl ketone, propyl vinyl ketone and phenyl vinyl ketone;

(m9) Olefins such as ethylene, propylene, isobutylene, butadiene and isoprene;

(m10) N-vinylpyrrolidone, acrylonitrile and methacrylonitrile;

(m11) Unsaturated imides such as maleimide, N-acryloyl acrylamide, N-acetyl methacrylamide, N-propionyl methacrylamide and N-(p-chlorobenzoyl)methacrylamide; and

(m12) Unsaturated carboxylic acids such as acrylic acid, methacrylic acid, maleic anhydride and itaconic acid.

In the case where the alkali-soluble polymer in the printing plate precursor to be used in the invention is a homopolymer or copolymer of the aforementioned polymerizable monomer having a phenolic hydroxyl group, polymerizable monomer having a sulfonamide group or polymerizable monomer having an active imide group, it preferably has a weight-average molecular., weight of not caller than 2,000, more preferably from 5,000 to 300,000, or a number-average molecular weight of not smaller than 500, more preferably from 900 to 250,000, and a dispersion degree (weight-average molecular weight/number-average molecular weight) of from 1.1 to 10.

Alternatively, in the case where the alkali-soluble polymer is a resin such as phenol formaldehyde resin and cresol aldehyde resin, it preferably has a weight-average molecular weight of from 500 to 20,000 or a number-average molecular weight of from 200 to 10,000.

In the printing plate precursor to be used in the invention, the alkali-soluble polymer to be incorporated in the upper layer is preferably a novolac resin such as cresol formaldehyde resin from the standpoint of image-forming properties and solubility in coating solvent.

The alkali-soluble polymer to be incorporated in the lower layer is preferably an alkali-soluble polymer compound having a sulfonamide group (2) or an alkali-soluble polymer compound having an active imide group (3) from the standpoint of solubility in developer and solubility in coating solvent.

These alkali-soluble polymer compounds maybe used singly or in combination of two or more thereof in an amount of from 30 to 99% by weight, more preferably from 40 to 95% by weight, particularly from 50 to 90% by weight based on the total weight of the solid content in the lower layer. When the content of the alkali-soluble polymer falls below 30% by weight, the resulting lower layer exhibits a deteriorated durability. On the contrary, when the content of the alkali-soluble polymer exceeds 99% by weight, it is disadvantageous in both sensitivity and durability.

[Infrared Absorbent]

The infrared absorbent (hereinafter occasionally referred to as “infrared-absorbing dye”) to be incorporated in the printing plate precursor of the invention is not specifically limited so far as it is a dye which absorbs infrared rays to generate heat. Various dyes known as infrared-absorbing dyes may be used.

As the infrared-absorbing dyes according to the invention there maybe used commercially available dyes and known compounds described in references (e.g., “Senryo Binran (Handbook of Dyes)”, The Society of Synthetic Organic Chemistry, Japan, 1970) Specific examples of these infrared-absorbing dyes include azo dye, metal complex azo dye, pyrazolone azo dye, anthraquinone dye, phthalocyanine dye, carbonium dye, qainonixmine dye, methine dye and cyanine dye. Particularly preferred among these dyes are those which absorb infrared rays or near infrared rays because they are suitable for use in lasers emitting infrared rays or near infrared rays.

Examples of the dyes which absorb infrared rays or near infrared rays include cyanine dyes as disclosed in Japanese Patent Laid-Open No. 1983-125246, Japanese Patent Laid-Open No. 1984-84356, Japanese Patent Laid-Open No. 1984-202829 and Japanese Patent Laid-Open No. 1985-78787, methine dyes as disclosed in Japanese Patent Laid-Open No. 1983-173696, Japanese Patent Laid-Open No. 1983-181690 and Japanese Patent Laid-Open No. 1983-194595, naphthoquinone dyes as disclosed in Japanese Patent Laid-Open No. 1983-112793, Japanese Patent Laid-Open No. 1983-224793, Japanese Patent Laid-Open No. 1984-48187, Japanese Patent Laid-Open No. 1984-73996, Japanese Patent Laid-Open No. 1985-52940 and Japanese Patent Laid-Open No. 1985-63744, squalelium dyes as disclosed in Japanese Patent Laid-Open No. 1983-112792, and cyanine dyes as disclosed in British Patent 434,875.

Alternatively, as such dyes there are preferably used near infrared-absorbing sensitizers as disclosed in U.S. Pat. No. 5,156,938. Further, substituted arylbenzo(thio)pyrilium salts an disclosed in U.S. Pat. No. 3,881,924, trimethine thiapyrilium salts as disclosed in Japanese Patent Laid-Open No. 1982-142645 (U.S. Pat. No. 4,327,169), pyrilium-based compounds as disclosed in Japanese Patent Laid-Open No. 1983-181051, Japanese Patent Laid-Open No. 1983-220143, Japanese Patent Laid-Open No. 1984-41363, Japanese Patent Laid-Open. No. 1984-84248, Japanese Patent Laid-Open No. 1984-84249, Japanese.-Patent Laid-Open No. 1984-146063 and Japanese Patent Laid-Open No. 1984-146061, cyanine dyes as disclosed in Japanese Patent Laid-Open No. 1984-216146,. pentamethine thiopyrilium salts as disclosed in U.S. Pat. No. 4,283,475, and pyrilium compounds as disclosed in U.S. Pat. No. 4,283,475 are preferably used. As commercially available dyes there are preferably used Epolight III-178, Epolight III-130 and Epolight III-125, which are produced by Npolin, Inc.

Other particularly preferred examples of these dyes include near infrared-absorbing dyes described as those of the general formulae (I) and (II) in U.S. Pat. No. 4,756,993.

The infrared absorbent maybe incorporated in the printing plate precursor of the invention in a proportion of from 0.01 to 50% by weight, preferably from 0.1 to 50% by weight, particularly from 0.1 to 30% by weight based on the total solid content. When the added amount of the dye falls below 0.01% by weight, a tendency is given that the resulting sensitivity decreases. On the contrary, when the added amount of the dye exceeds 50% by weight, a tendency is given that the uniformity of the various layers can be lost and the durability of the various layers can be deteriorated.

[Solubility-Inhibiting Compound]

For the purpose of enhancing the inhibition (of dissolution) of the printing plate precursor to be used in the invention, various inhibitors may be incorporated in the image-recording layer.

These inhibitors employable herein are not specifically limited. In practice, however, quaternary ammonium salts, polyethylene glycol-based compounds, etc. may be used.

The quaternary anmonium salts employable herein are not specifically limited. In practice, however, tetraalkyl ammonium salts, trialkyl aryl ammonium salts, dialkyl diaryl ammonium salts, alkyl triaryl ammonium salts, tetraaryl ammonium salts, cyclic ammonium salts and bicyclic ammonium salts may be used.

Specific examples of these quaternary anmonium salts include tetrabutyl ammonium bromide, tetrapentyl amonium bromide, tetraoctyl ammonium bromide, tetralauryl ammonium bromide, tetraphenyl ammonium bromide, tetranaphthyl ammonium bromide, tetrabutyl ammonium bromide, tetrabutyl ammonium iodide, tetrastearyl ammonium bromide, lauryl trimethyl ammonium broide, stearyl trimethyl amonium bromide, behenyl trimethyl monium bromide, lauryl triethyl ammonium bromide, phenyl trimethyl ammonium bromide, 3-trifluoromethyl phenyl trimethyl amonium bromide, benzyl trimethyl ammonium bromide, dibentyl dimethyl ammonium bromide, distearyl dimethyl ammonium bromide, tristearyl methyl ammonium bromide, benzyl triethyl ammonium bromide, hydroxyphenyl trimethyl ammonium bromide, and N-methylpyridinium bromide.

The added amount of the quaternary ammonium salt is preferably from 0.1 to 50% more preferably from 1 to 30% based on the total solid content in the image-recording layer as calculated in terms of solid content. When the added amount of the quaternary ammonium salt falls below 0.1%, the resulting effect of inhibiting solubility is lessened to disadvantage. On the contrary, when the added amount of the quaternary ammonium salt exceeds 50%, it gives an adverse effect on the film-forming properties of the binder.

The polyethylene glycol compound mevloyable herein is not specifically limited. In practice, however, those having the following structures may be used.

R¹—{—O—(R³—O—)ₘ—R²}ₙ

wherein R¹ represents a polyvalent alcohol residue or polyvalent phenol residue; R² represents a C₁-C₂₅ alkyl, alkenyl, alkinyl, alkyloyl, aryl or aryloyl group which may have substituents; R³ represents an alkylene residue which may have substituents; m represents an integer of not smaller than 10 on the average; and n represents an integer of from not smaller than 1 to not greater than 4 on the average.

Examples of the polyethylene glycol compound having the aforementioned structure include polyethylene glycols, polypropylene glycols, polyethylene glycol alkyl ethers, polypropylene glycol alkyl ethers, polyethylene glycol aryl ethers, polypropylene glycol aryl ethers, polyethylene glycol alkyl aryl ethers, polypropylene glycol glycerin esters, polypropylene glycol glycerin esters polyethylene sorbitol esters, polypropylene glycol sorbitol esters, polyethylene glycol aliphatic esters, polypropylene glycol aliphatic esters, polyethylene glycolated ethylenediarnines, polypropoylene glycolated ethylenediamines, polyethylene glycolated diethylenetrinines, and polypropylene glycolated diethylenetriamines.

Specific examples of these polyethylene glycol compounds include polyethylene glycol 1000, polypropylene glycol 2000, polypropylene glycol 4000, polypropylene glycol 10000, polypropylene glycol 20000, polypropylene glycol 50000, polypropylene glycol 100000, polypropylene glycol 200000, polypropylene glycol 500000, polypropylene glycol 1500, polypropylene glycol 3000, polypropylene glycol 4000, polypropylene glycol methyl ether, polypropylene glycol ethyl ether, polypropylene glycol phenyl ether, polypropylene glycol dimethyl ether, polypropylene glycol diethyl ether, polypropylene glycol diphenyl ether, polypropylene glycol lauryl ether, polypropylene glycol dilauryl ether, polypropylene glycol nonyl ether, polypropylene glycol cetyl ether, polypropylene glycol stearyl ether, polypropylene glycol distearyl ether, polypropylene glycol behenyl ether, polypropylene glycol dibehenyl ether, polypropylene glycol methyl ether, polypropylene glycol ethyl ether, polypropylene glycol phenyl ether, polypropylene glycol dirnethyl ether, polypropylene glycol diethyl ether, polypropylene glycol diphenyl ether, polypropylene glycol lauryl ether, polypropylene glycol dilauryl ether, polypropylene glycol. nonyl ether, polypropylene glycol acetyl ester, polypropylene glycol diacetyl ester, polypropylene glycol benzoic acid ester, polypropylene glycol lauryl ester, polypropylene glycol dilauryl ester, polypropylene glycol nonylic acid ester, polypropylene glycol cetylic acid ester, polypropylene glycol stearoyl ester, polypropylene glycol distearoyl ester, polypropylene glycol behenic acid ester, polypropylene glycol dibehenic acid ester, polypropylene glycol acetyl ester, polypropylene glycol diacetyl ester, polypropylene glycol benzoic acid ester, polypropylene glycol dibenzoic acid ester, polypropylene glycol lauric acid ester, polypropylene glycol dilauric acid ester, polypropylene glycol nonylic acid ester, polypropylene glycol glycerin ether, polypropylene glycol glycerin ether, polypropylene glycol sorbitol ether, polypropylene glycol sorbitol ether, polypropylene glycolated ethylenediamine, polypropylene glycolated ethylenediamine, polypropylene glycolated diethylenetriamine, polypropylene glycolated diethylenetriamine, and polypropylene glycolated pentamethylenehexamine.

The added amount of the polyethylene glycol-based compound is preferably from 0.1 to 50%, more preferably from 1 to 30% based on the total solid content in the image-recording layer as calculated in terms of solid content. When the added amount of the polyethylene glycol-based compound falls below 0.1%, the resulting effect of inhibiting solubility is low to disadvantage. On the contrary, when the added amount of the. polyethylene glycol-based compound exceeds 50%, the polyethylene glycol-based compound which cannot interact with the binder can accelerate the penetration of the developer to have an adverse effect on the image-forming properties.

When the aforementioned enhancement of inhibition (of dissolution) is effected, the reduction of sensitivity occurs. In this case, the addition of a lactone compound is effective. It is thought that when the developer penetrates the exposed area, it reacts with this lactone compound to produce a carboxylic acid compound, making contribution to the dissolution of the exposed area and hence enhancing the sensitivity.

The lactone compound employable herein is not specifically limited. In practice, however, compounds represented by the following general formulae (L-I) and (L-II) may be used.

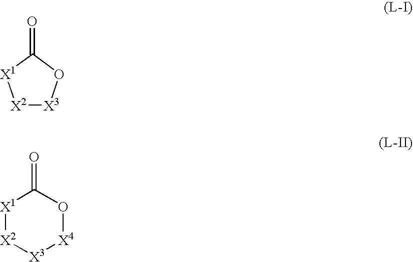

In the general formulae (L-I) and (L-II), X¹, X², X³ and X⁴ may be the same or different and each represent a ring-forming atom or atomic group. X¹, X², X³ and X⁴ each may independently have a substituent. At least one of X¹, X² and X³ in the general formula (L-I) and at least one of X¹, X², X³ and X⁴ in the general formula (L-II) have a substituent substituted by an electrophilic substituent or electrophilic group.

The ring-forming atom or atomic group represented by X¹, X², X³ or X⁴ is a nonmetallic atom or nonmetallic atom-containing atomic group having two single bonds for forming a ring.

Preferred examples of the nonmetallic atom or nonmetallic atom group include atom or atomic group selected from the group of consisting of methylene group, sulfonyl group, carbonyl group, thiocarbonyl group, sulfonyl group, sulfur atom, oxygen atom and selenium atom, more preferably atomic group selected from the group consisting of methylene group, carbonyl group and sulfonyl group.

At least one of X¹, X² and X³ in the general formula (L-I) and at least one of X¹, X², X³ and X⁴ in the general formula (L-II) have an electrophilic group. The term “electrophilic substitutent” as used herein is meant to indicate a group having a Hammett's substituent constant up which is a positive value. For details of Hammett's substituent constant, reference can be made to “Journal of Medicinal Chemistry”, 1973, Vol. 16, No.11, 1207-1216. Examples of the electrophilic group having a Hammett's substituent constant op which is a positive value include halogen atoms (fluorine (op value: 0.06), chlorine (op value: 0.23), bromine (op value: 0.23), iodine (op value: 0.18)), trihaloalkyl group (tribromomethyl (op value: 0.29), trichloromethyl (op value: 0.33), trifluoromethyl (up value: 0.54)), cyano group (op value: 0.66), nitro group (op value: 0.78), aliphatic aryl or heterocyclic sulfonyl group (e.g., methanesulfonyl (op value: 0.72)), aliphatic aryl or heterocyclic acyl group (e.g., acetyl (op value: 0.50), benzoyl (op value: 0.43)), alkinyl group (e.g., C═CH (op value: 0.23)), aliphatic aryl or heterocyclic ozycarbonyl group (e.g., methoxycarbonyl (op value: 0.45), phenoxycarbonyl (op value: 0.44)), carbamoyl group (op value: 0.36), sulfamoyl group (op value; 0.57), sulfoxide group, heterocyclic group, oxo group, and phosphoryl group.

Preferred electrophilic groups are selected from the group consisting of amide group, azo group, nitro group, C₁-C₅ fluoroalkyl group, nitrile group, C₁-C₅ alkoxycarbonyl group, C₁-C₅ acyl group, C₁-C₉ alkylsulfonyl group, C₆-C₉ arylsulfonyl group, C₁-C₉ alkylsulfinyl group, C₆-C₉ arylaulfinyl group, C₆-C₉ arylcarbonyl group, thiocarbonyl group, C₁-C₉ fluorine-containing alkyl group, C₆-C₉ fluorine-containing aryl group, C₃-C₉ fluorine-containing allyl group, oxo group, and halogen atom.

More preferably, there are used those selected from the group consisting of nitro group, C₁-C₅fluoroalkyl group, nitrile group, C₁-C₅ alkoxycarbonyl group, C₁-C₅ acyl group, C₆-C₉ arylsulfonyl group, C₆-C₉ arylaulfinyl group, C₆-C₉ arylcarbonyl group, oxo group, and halogen atom.

Specific examples of the compounds represented by the general formulae (L-I) and (L-II) will be given below, but the invention is not limited thereto.

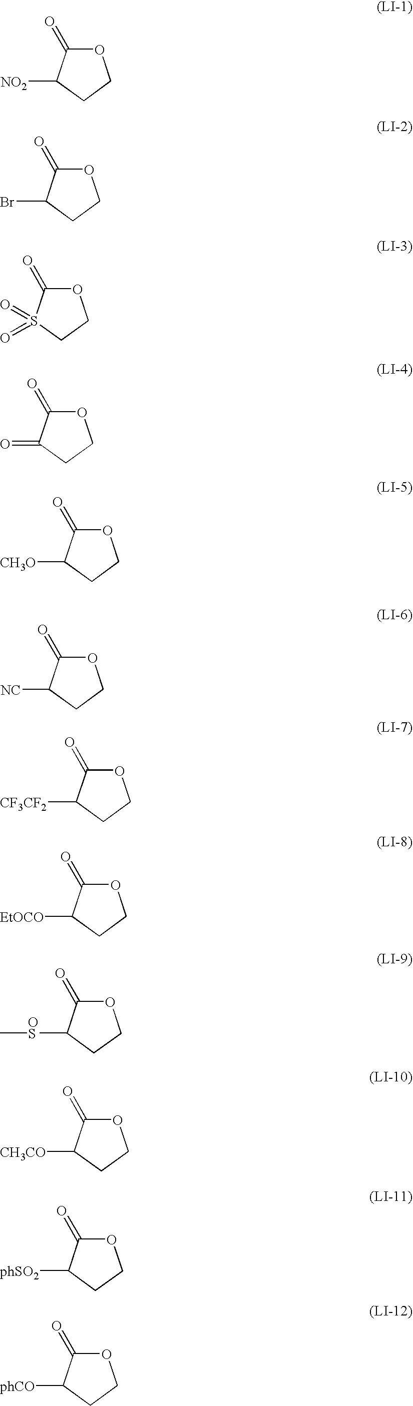

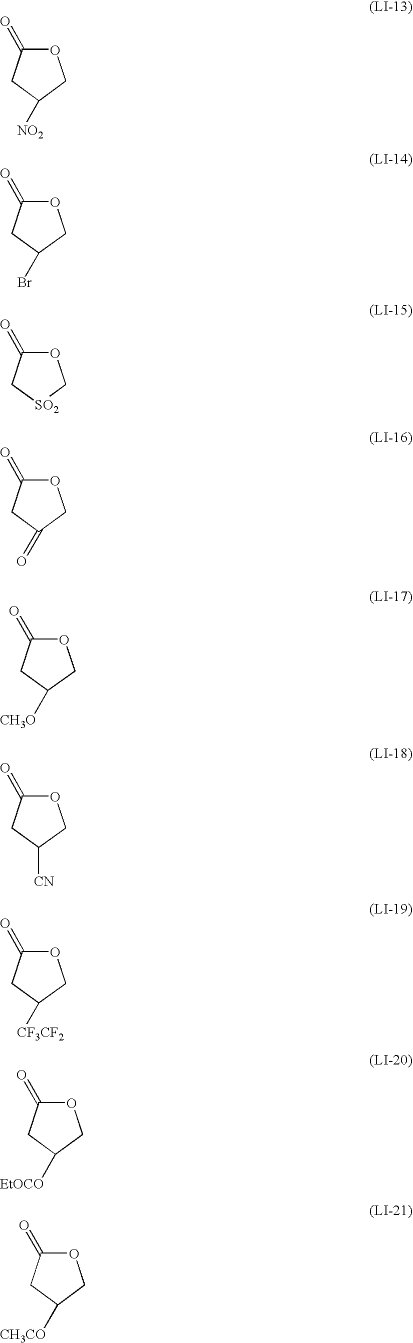

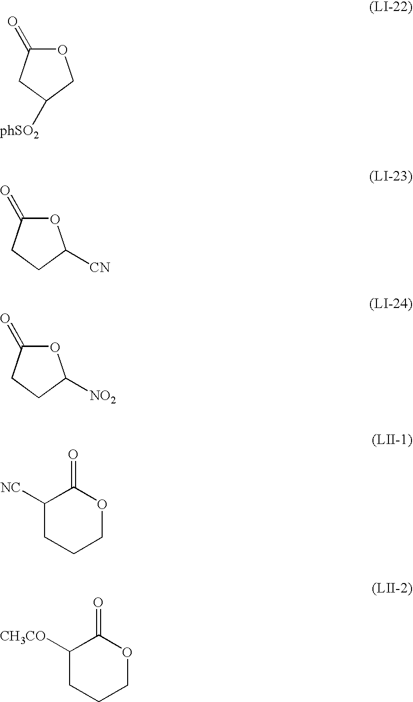

The amount of the compounds represented the general formulae (L-I) and (L-II) to be incorporated is preferably from 0.1 to 50%, preferably from 1 to 30% based on the total solid content in the image-recording layer as calculated in terms of solid content. When the amount of the compounds represented the general formulae (L-I) and (L-II) to be incorporated falls below 0.1%, the resulting effect is insufficient. On the contrary, when the amount of the compounds represented the general formulae (L-I) and (L-II) to be incorporated exceeds 50%, the resulting printing plate precursor exhibits deteriorated image-forming properties. Since this compound reacts with the developer, it is preferred that this compound comes in selective contact with the developer.

These lactone compounds may be used singly or in combination. Alternatively, two or more of the lactone compounds of the general formula (L-I) or two or more of the lactone compounds of the general formula (L-II) may be used in combination in a total amount falling within the above defined range.

Further, the printing plate precursor of the invention preferably comprises a heat-decomposable material which substantially lowers the solubility of the alkali-soluble resin when it stays thermally undecomposed for the purpose of further expanding the discrimination between the exposed area and the unexposed area.

The heat-decomposable material which substantially lowers the solubility of the alkali-soluble resin when it stays thermally undecomposed is not specifically limited. In practice, however, various onium salts and quinonediazide compounds may be used. Particularly preferred among these materials are onium salts from the standpoint of heat decomposability.

Examples of the onium salts employable herein include diazonium salt, ammonium salt, phosphonium salt, iodonium salt, sulfonium salt, selenonium salt, and arsonium salt. Preferred examples of the onium salts employable herein include diazonium salts as disclosed in S. I. Schlesinger., “Photogr. Sci. Eng.”, 18, 387 (1974), T. S. Bal et al, “Polymer”, 21, 423 (1980), and Japanese Patent Laid-Open No. 1993-158230,ammonium salts as disclosed in U.S. Pat. Nos. 4,069,055, 4,069,056, U.S. Pat. No. Re 27,992, and Japanese Patent Application No. 1992-140140, phosphonium salts as disclosed in D. C. Necker et al, “Macromolecules”, 17,2468 (1984),C. S. Wenetal, “Teh, Proc. Conf. Rad. Curing”, ASIA, page 478, Tokyo, October 1988, U.S. Pat. Nos. 4,069,055, and 4,069,056., iodonium salts as disclosed in J. V. Crivello et al, “Macromorecules”, 10 (6), 1307 (1977), “Chem. & Eng. News”, Nov. 28, 1988, page 31, European Patent 104,143, U.S. Pat. Nos. 339,049, 410,201, Japanese Patent Laid-Open No. 1990-150848, and Japanese Patent Laid-Open No.1990-296514, sulfonium salts as disclosed in J. V. Ctivello et al, “Polymer J.”, 17, 73 (1985), J. V. Crivello et al, “J. Org. Chem.”, 43, 3055 (1978), W. R. Watt et al, “J. Polymer Sci.”, Polymer Chem. Ed., 22, 1789 (1984), J. V. Crivello et al, “Polymer Bull.”, 14, 279 (1985), J. V. Crivello et al, “Macromorecules”, 14 (5), 1141 (1981), J. V. Crivello et al, “J. Polymer Sci.”, Polymer Chem. Ed., 17,2877 (1979), European Patent 370,693, European Patent 3,902,114, European Patent 233,567, European Patent 297,443, European Patent 297,442, U.S. Pat. Nos. 4,933,377, 161,811, 410,201, 339,049, 4,760,013, 4,734,444, 2,833,827, German Patent 2,904,626, German Patent 3,604,580, and German Patent 3,604,581, selenonium salts as disclosed in J. V. Crivello et al, “Macromoreculeas”, 10 (6)., 1307 (1979), and J. V. Crivello et al, “J. Polymer Sci.”, Polymer Chem. Ed., 17, 1047 (1979), and arsonium salts as disclosed in C. S. Wen et al, “Teh, Proc. Conf. Rad. Curing”, ASIA, page 478, Tokyo, October 1988.

In the printing plate precursor of the invention, diazonium salts are particularly preferred. Particularly preferred examples of the diazonium salt include those described in Japanese Patent Laid-Open No. 1993-158230.

Examples of counter ions for these onium salts include tetrafluoroboric acid, hexafluorophosphoric acid, triisopropylnaphthalenesulfonic acid, 5-nitro-o-toluenesulfonic acid, 5-sulfosalicylic acid, 2,5-dimethylbenzenesulfonic acid, 2,4,6-trimethylbenzenesulfonic acid, 2-nitrobenzenesulfonic acid, 3-chlorobenzenesulfonic acid, 3-bromobenzenesulfonic acid, 2-fluorocaprylnaphthalenesulfonic acid, dodecylbenzenesulfonic acid, 1-nanpthaol-5-sulfonic acid, 2-methoxy-4-hydroxy-5-benzoyl-benzenesulfonic acid, and paratoluenesulfonic acid. Particularly preferred among these counter ions are hexafluorophosphoric acid and alkyl aromatic sulfonic acid such as triisopropylnaphthalenesulfonic acid and 2,5-dimethyl benzenesulfonic acid. The added amount of these materials is preferably from 0.1 to 50% by weight, more preferably from 0.1 to 30% by weight, particularly from 0.3 to 30% by weight.

Preferred examples of the quinonediazides include o-quinonediazide compounds. The o-quinonediazide compounds to be used in the invention are compounds each having at least oleo-quinonediazide group which become more soluble in an alkali upon heat decomposition. As these o-quinonediazide compounds there maybe used compounds having various structures. In other words, o-quinonediazide helps the dissolution of the lower layer by exerting both the effects of losing the capability of inhibiting the dissolution of the alkali-soluble resin and converting itself to an alkali-soluble material upon heat decomposition. As the o-quinonediazide compounds to be used in the invention there may be used compounds described in J. Corsa, “Light-sensitive Systems”, John Wiley a Sons. Inc., pp. 339-352. In particular, sulfonic acid esters or sulfonic acid amiden of o-quinonediazide obtained by the reaction of o-quinonediazide with various aromatic polyhydroxy compounds or aromatic amino compounds are preferred. Further, there are preferably used esters of benzoquinone (1,2)-diazidesulfonic acidchlorideornaphthoquinone-(1,2)-diazide-5-sulfonic acid chloride with pyrogallol-acetone resin as described in Japanese Patent Publication No. 1968-28403 and esters of benzoquinone-(1,2)-diazidesulfonic acid chloride or naphthoquinone-(12)-diazide-5-sulfonic acid chloride with phenol-formaldehyde resin as described in U.S. Pat. Nos. 3,046,120 and 3,188,210.

Moreover, esters of naphthoquinone-(1,2)-diazide-4-sulfonic acid-chloride with phenol-formaldehyde resin or cresol-formaldehyde resin and esters of naphthoquinone-(1,2)-diazide-4-sulfonic acid chloride with pyrogallol-acetone resin are preferably used. Other useful examples of o-quinonediazide compounds have been reported and known in many patents, e.g., Japanese Patent Laid-Open No. 1972-5303, Japanese Patent Laid-Open No. 1973-63802, Japanese Patent Laid-Open No.1973-63803, Japanese Patent Laid-Open No. 1973-96575, Japanese Patent Laid-Open No. 1974-38701, Japanese Patent Laid-Open No.1973-13354, Japanese Patent Publication No. 1966-11222, Japanese Patent Publication No. 1970-9610, Japanese Patent Publication No. 1974-17481, U.S. Pat. Nos. 2,797,213, 3,454,400, 3,544,323, 3,573,917, 3,674,495, 3,785,825, British Patent 2,227,602, British Patent 1,251,345, British Patent 1,329,888, British Patent 1,330,932, German Patent 854,890. The added amount of the o-quinonediazide compounds is preferably from 1 to 50% by weight, more preferably from 5 to 30% by weight, particularly from 10 to 30% by weight based on the total solid content in the lower layer. These compounds may be used singly or in admixture. When the added amount of the o-quinonediazide compounds falls below 1% by weight, the resulting printing plate precursor exhibits deteriorated image-recording properties. On the contrary when the added amount of the o-quinonediazide compounds exceeds 50% by weight, the image area exhibits a deteriorated durability or sensitivity.

More preferably, the heat-decomposable material is an onium salt from the standpoint of decomposability.

It is thought that the use of this onium salt having a high heat-decomposability causes further acceleration of decomposition of the heat-decomposable material in the exposed area, making it possible to enhance the discrimination between the exposed area and the unexposed area.

However, the heat-decomposable material which substantially lowers the solubility of the alkali-soluble resin when it stays thermally undecomposed is preferably incorporated in the lower layer from the standpoint of safety under white light. Further, the use of a solvent for inhibiting the solubility of the lower layer component, which is one of the requirements of the invention, is particularly desirable because it prevents the heat-decomposable material from being eluted with the upper layer. A particularly preferred example of the onium salt is a diazonium salt.

The printing plate precursor of the invention comprises an image-recording layer containing the aforementioned components as main components provided on a support. The image-recording layer may have a multi-layer structure consisting of at least two layers (A two-layer structure consisting of upper recording layer and lower recording layer will be described herein after for convenience. The terms “lower recording layer and upper recording layer” are used herein to distinguish from the aforementioned underlayer (lower layer) provided interposed between the image-recording layer and the support.).

As the alkali-soluble resin forming the upper recording layer and the lower recording layer there may be used the alkali-soluble resin described above. The alkali-soluble resin for the upper recording layer preferably has a lower solubility in an alkali than that for the lower recording layer.

Different infrared absorbents may be incorporated in different layers. Alternatively, the various layers may each comprise an infrared absorbent-made of a plurality of compounds incorporated therein. The amount of such an infrared absorbent to be incorporated is from 0.01 to 50% by weight, preferably from 0.1 to 50% by weight, particularly from 0.1 to 30% by weight based on the total solid content in the layer regardless of which layer it is incorporated in as mentioned above. In the case where the infrared absorbent is incorporated in a plurality of layers, the total amount of the infrared absorbents to be incorporated in these layers preferably falls within the above defined range.

The heat-decomposable material which substantially lowers the solubility of the alkali-soluble resin when it stays thermally undecomposed can partially decompose with time, Therefore, in the case where the image-recording layer has a multi-layer structure, it is effective to incorporate the heat-decomposable material in the lower recording layer, but the heat-decomposable material may be incorporated in either or both of the upper recording layer and the lower recording layer. The amount of the heat-decomposable material to be incorporated is as defined above. In the case where the heat-decomposable absorbent is incorporated in a plurality of layers, the total amount of the heat-decomposable absorbent to be incorporated in these layers preferably falls within the above defined range.

In the case where the image-recording layer has a multi-layer structure, it in effective to incorporate the lactone compound in the upper recording layer, but the lactone compound may be incorporated in either or both of the upper recording layer and the lower recording layer.

[Other Components]

In order to form the aforementioned image-recording layer, various additives may be optionally added besides the aforementioned essential components so far as the effect of the invention cannot be impaired. The invention will be further described with reference to examples of these additives.

For example, a polymer comprising as a polymer component a (meth)acrylate monomer having two or three C₃-C₂₀ perfluoroalkyl groups per molecule as described in Japanese Patent Laid-Open No. 2000-187318 may be additionally used for the purpose of enhancing the discrimination between the image area and the non-image area and the scratch resistance of surface, Such a compound maybe incorporated in either the upper recording layer or the lower recording layer but is effectively incorporated in the lower recording layer.

The amount of such a compound to be incorporated is preferably from 0.1 to 10% by weight, more preferably from 0.5 to 5% by weight based on the layer material.

The printing plate precursor of the invention may comprise a compound for lowering the static coefficient of friction of surface thereof incorporated therein for the purpose of rendering itself resistant to scratch. Specific examples of such a compound include long-chain alkyl carboxylic acid esters as used in U.S. Pat. No. 6,117,913. In the case where the image-recording layer has a multi-layer structure, such a compound may be incorporated in either the lower recording layer or the upper recording layer but is effectively incorporated in the upper recording layer.

The amount of such a compound to be incorporated is preferably from 0.1 to 10% by weight, more preferably from 0.5 to 5% by weight based on the layer-forming material.

The printing plate precursor of the invention may further comprise a low molecular acidic group incorporated therein as necessary. Examples of the acidic group employable herein include sulfonic acid, carboxylic acid, and phosphoric acid. In particular, compounds having sulfonic acid group are preferred. Specific examples of these sulfonic acids include aromatic sulfonic acids such as p-toluenesulfonic acid and naphthalene sulfonic acid, and aliphatic sulfonic acids.

Such a compound may be incorporated in either the lower recording layer or the upper recording layer in the case where the image-recording layer has a multi-layer structure. The amount of such a compound to be incorporated is preferably from 0.05 to 5% by weight, more preferably from 0.1 to 3% by weight based on the layer-forming material. When the amount of such a compound to be incorporated exceeds 5% by weight, the resulting layers have a raised solubility in the developer to disadvantage.

The printing plate precursor of the invention may comprise a compound having a high interaction incorporated therein for the purpose of enhancing the discrimination between the image area and the non-image area. As a dissolution inhibitor there is preferably used a disulfone compound or sulfone compound as disclosed in Japanese Patent Laid-Open No. 1999-119418. Specific examples of such a compound employable herein include 4,4′-bishydroxyphenylsulfone.

Such a compound may be incorporated in either the lower recording layer or the upper recording layer in the case where the image-recording layer has a multi-layer structure. The amount of such a compound to be incorporated is preferably from 0.05 to 20% by weight, more preferably from 0.5 to 10% by weight based on the layer-forming material.

The printing plate precursor of the invention may further comprise cyclic acid anhydrides, phenols and organic acids incorporated therein for the purpose of enhancing the sensitivity thereof. Examples of the cyclic acid anhydrides employable herein include phthalic anhydride, tetrahydrophthalic anhydride, hexahydrophthalic anhydride, 3,6-endoxy-Δ4-tetrahydrophthalic anhydride, tetrachlorophthalic anhydride, maleic anhydride, chloromaleic anhydride, α-phenylmaleic anhydride, succlnic anhydride and pyromellitic anhydride as described in U.S. Pat. No. 4,115,128. Examples of the phenols employable herein include bisphenol A, p-nitrophenol, p-ethoxyphenol, 2,4,4′-trihydroxybenzophenone, 2,3,4-trihydroxybenzophenone, 4-hydroxybenzophenone, 4,4′,4″-trihydroxytriphenylmethane, and

4,4′,3″,4″-tetrahydroxy-3,5,3′,5,-tetramethyltriphenylmeth ane. Examples of the organic acids employable herein include sulfonic acids, sulfonic acids, alkyl sulfuric acids, phosphonic acids, phosphoric acid esters, and carboxylic acids as described in Japanese. Patent Laid-Open No. 1985-88942 and Japanese Patent Laid-Open No. 1990-96755. Specific examples of these organic acids include p-toluenesulfonic acid, dodecylbenzenesulfonic acid, p-toluenesulfonic acid, ethyl sulfuric acid, phenyl phosphonic, acid, phenylphosphinic acid, phenyl phosphate, diphenyl phosphate, benzoic acid, isophthalic acid, adipic acid, p-toluic acid, 3,4-dimethoxybenzoic acid, phthalic acid, terephthalic acid, 4-cyclohexene-1,2 -dicarboxylic acid, erucic acid, lauric acid, n-undecanoic acid, and ascorbic acid. The proportion of the aforementioned cyclic acid anhydrides, phenols and organic acids to be in the layer-forming material is preferably from 0.05 to 20% by weight, more preferably from 0.1 to 15% by weight, particularly from 0.1 to 10% by weight.

The coating solution for image-recording layer may comprise anonionic surface active agent as described in Japanese Patent Laid-Open No. 1987-251740 and Japanese Patent Laid-Open No.1992-208514, an amphoteric surface active agent as described in Japanese Patent Laid-Open No. 1984-121044and Japanese Patent Laid-Open No. 1992-13149, a siloxane-based compound as described in EP950517 and a fluorine-containing monomer copolymer as described in Japanese Patent Laid-Open No. 1999-288093 incorporated therein for the purpose of expanding the stability in processing against the development conditions.

These additives may be incorporated in either or both of the lower recording layer and the upper recording layer in the case where the image-recording layer has a multi-layer structure.

Specific examples of the nonionic surface active agent employable herein include sorbitan tristearate, sorbitan monopalmitate, sorbitan trioleate, monoglyceride stearate, and polyozyethylone nonyl phenyl ether. Specific examples of the amphoteric surface active agent employable herein include alkyl di(aminoethyl)glycine, alkyl polyaminoethyl glycine hydrochloride,

2-alkyl-N-carboxyethyl-N-hydroxyethylimidazolinium betaine, and N-tetradecyl-N,N-betaine (e.g., “Amogen K”, produced by DAI-ICHI KOGYO SEIYAKU CO,. LTD.).

Preferred examples of the siloxane-based compound employable herein include block copolymers of dimethyl siloxane with polyalkylene oxide. Specific examples of these block copolymers include polyalkylene oxide-modified silicones such as DBE-224, DBE-621, DBE-712, DBP-732 and DBP-534, which are produced by CHISSO CORPORATION, and Tego Glide 100, produced by Tego Chemie Service GmbH of Germany.

The proportion of the aforementioned nonionic surface active agent and amphoteric surface active agent in the coating solution material is preferably from 0.05 to 15% by weight, more preferably from 0.1 to 5% by weight.

The Image-recording layer may comprise a printing-out agent for providing a visible image shortly after heating by exposure or a dye or pigment as an image colorant.

A representative example of the printing-out agent is a combination of a compound which releases an acid when heated by exposure (photo-acid releaser) and an organic dye capable of forming a salt. Specific examples of such a combination include a combination of o-naphthoqninonediazide-4-sulfonic acid halogenide and a salt-forming organic dye as disclosed in Japanese Patent Laid-Open No.1975-36209 and Japanese Patent Laid-Open No. 1978-8128, and a combination of a trihalomethyl compound and a salt-forming organic dye as described in Japanese Patent Laid-Open No. 1978-36223, Japanese Patent Laid-Open No. 1979-74728, Japanese Patent Laid-Open No. 1985-3626, Japanese Patent Laid-Open No. 1986-143748, Japanese Patent Laid-Open No. 1986-151644 and Japanese Patent Laid-Open No. 1988-58440. Examples of such a trihalomethyl compound include oxazole-based compound and triazine-based compound. Both the two compounds are excellent in age stability and give a definite printed image.

As the image colorants there may be used other dyes besides the aforementioned salt-forming organic dyes. As desirable dyes there may be used oil-soluble dyes and basic dyes, including salt-forming organic dyes. Specific examples of these oil-soluble dyes and basic dyes include Oil Yellow #101, Oil Yellow #103, Oil Pink #312, Oil Green BG, Oil Blue BOS, Oil Blue #603r Oil Black BY, Oil Black BS, Oil Black T-505 (produced by Oriental Chemical industries, Ltd.), Victoria Purai Blue, Crystal Violet (CI42555), Methyl Violet(CI42535), Ethyl Violet, Rhodamine B (CI145170B), Malachite Green. (CI42000)., and Methylene Blue (CI52015). Dyes described in Japanese Patent Laid-Open No. 1987-293247 are particularly preferred. These dyes are incorporated in the printing plate material in an amount of from 0.01 to 10% by weight, preferably from 0.1 to 3% by weight based on the total solid content in the printing plate material.

These dyes may be incorporated in either or both of the lower recording layer and the upper recording layer in the case where the positive-working image-recording layer has a multi-layer structure.

The printing plate material of the invention comprises a plasticizer incorporated therein for providing the coat layer with flexibility or the like as necessary. Examples of the plasticizer employable herein include butyl phthalyl, polyethylene glycol, tributyl citrate, diethyl phthalate, dibutyl phthalate, dihexyl phthalate, dioctyl phthalate, tricresyl phosphate, tributyl phosphate, trioctyl phosphate, tetrahydrofurfuryl oleate, and oligomer and polymer of acrylic acid and methacrylic acid.

The lower layer normally comprises a dissolution-accelerating component incorporated therein to predetermine the solubility of the lower layer to be higher than that of the upper layer. As the component capable of accelerating dissolution there may be used a compound having an acid group and little hydrophobic substituent. Examples of such a compound include bisphenol A, bisphenol S, bisphenol Z, benzoic acid, alkyl-substituted benzoic acid, toluenesulfonic acid, hydroquinone, and pyrogallol. Besides these compounds, the aforementioned cyclic acid anhydrides, phenols and organic acids may be used.

The printing plate precursor at which the invention is aimed can be prepared by dissolving the various components forming the image-recording layer and the lower layer in separate solvents to prepare an image-recording layer coating solution and an underlayer coating solution, respectively, and then sequentially applying the lower layer coating solution and the image-recording layer coating solution to a proper support. The composition of the solvents for the image-recording layer coating solution and the lower layer coating solution can be properly predetermined depending on the respective constituents. Further, in the case where the image-recording layer has a multi-layer structure, too, the composition of the solvents for the upper recording layer and the lower recording layer can be each properly predetermined.

In the invention, in order to prepare the aforementioned image-recording layer coating solution, it is essential that as a solvent there be used a solvent which doesn't dissolve the lower layer component such as component capable of accelerating dissolution in an amount of 20% by weight or more, preferably 13% by weight or more, more preferably 10% by weight or more. When a solvent which doesn't dissolve the lower layer component is used in an amount of 13% by weight or more, the resistance of the photosensitive layer to developer can be further enhanced. When a solvent which doesn't dissolve the lower layer component in an amount of 10% by weight or more is used, the production stability, too, can be further enhanced. The use of such a solvent makes it possible to accomplish the aforementioned aim of the invention. The term “doesn't dissolve the lower layer component in an amount of 20%6 by weight or more” as used herein is meant to indicate that even when the solvent comes in contact with the surface of the lower layer, the eluted amount of the lower layer component falls below 20% by weight.

This means that in the case where the image-recording layer coating solution in applied to the support by means of a bar coater, there is repeatedly effected a procedure that the excessive coating solution is returned to a coating solution storage tank from which it is then fed again to the coating head of the bar coater, but in this case, too, the equilibrium concentration of the lower layer component in the image-recording layer coating solution falls below 20% by weight. The aforementioned problem of restriction of dissolution of the lower layer component in the solvent for the image-recording layer coating solution is a problem relative to solubility of lower layer component. The restriction of dissolution of the lower layer component in the solvent can be attained not only by the selection of the composition of the solvent but also by the control over the solubility of the lower layer component.

Examples of the solvent for the image-recording layer coating solution employable herein include ethylene dichloride, cyclohexanone, methyl ethyl ketone, methanol, ethanol, propanol, ethylene glycol monomethyl ether, 1-methoxy-2-propanol, 2methoxy ethyl acetate, 1-methoxy-2-propyl acetate, dimethoxyethane, methyl lactate, ethyl lactate, N, N-dimethylacetamide, N,N-dimethylformamide, tetramethylurea, N-methylpyrrolidone, dimethyl sulfoxide, sulfolane, γ-butyrolactone, and toluene. The invention is not limited to these solvents. These solvents may be used singly or in admixture. The optimum combination, mixing ratio and amount of these solvents are predetermined depending on the composition of the lower layer such that the dissolved amount of the lower layer is not greater than 20% by weight, preferably not greater than 13% by weight.

In general, cyclohexanone, methyl ethyl ketone, methanol, ethanol, propanol, liathoxy-2-propanol, etc. are preferably used, though depending on the composition of the lower layer.

In the invention, as described above, the image-recording layer coating solution is applied adjacent to the lower layer coating solution which has been applied. However, during this procedure, a problem arises that the component capable of accelerating the dissolution of the lower layer component elutes with the image-recording layer coating solution. Another problem arises. In other words, when as the solvent for the image-recording layer coating solution there is used a solvent capable of dissolving the alkali-soluble polymer of the lower layer, nonnegligible mixing can occur at the interface of the image-recording layer with the lower layer, causing the formation of a single layer rather than multi-layer in the extreme case. Thus, in the case where mixing or compatibilization occurs at the interface of two adjacent layers to show a behavior as a uniform layer, the effect exerted by the provision of two layers in the printing plate precursor at which the invention is aimed can be impaired to disadvantage. Therefore, the solvent to be used in the application of the Image-recording layer coating solution is preferably a solvent having a poor compatibility with the alkali-soluble polymer incorporated in the lower layer.

In the invention, the concentration of the various constituents (total solid content containing additives) of the coating solution for the various layers such as the aforementioned upper layer and lower layer, lower recording layer, upper recording layer in the case where the image-recording layer has a multi-layer structure can be properly predetermined an necessary but is normally preferably from 1 to 50% by weight.

In the case where the image-recording layer has a multi-layer structure, the coated amount of the upper recording layer and the lower recording layer (solid content) are preferably from 0.05 to 1.0 g/m² and from 0.3 to 3. 0 g/m², respectively, though depending on the purpose. When the coated amount of the upper recording layer falls below 0.05 g/m², the resulting image-recording layer exhibits deteriorated image-forming properties. On the contrary, when the coated amount of the upper recording layer exceeds 1.0 g/m², the resulting image-recording layer can have a lowered sensitivity. Further, the sum of the coated amount of the two layers is preferably from 0.5 to 3. 0 g/m². When the sum of the coated amount of the two layers falls below 0.5 g/m² the resulting image-recording layer exhibits deteriorated film properties. On the contrary, when the sum of the coated amount of the two layers exceeds 3.0 g/m², the resulting image-recording layer tends to have a lowered sensitivity. As the coated amount of the layers decreases, the apparent sensitivity of the image-recording layer increases, but the film properties of the upper recording layer and the lower recording layer deteriorates.

As the method for applying the lower layer and the image-recording layer to the support there may be used any of various methods. Examples of the coating method employable herein include bar coating method, rotary coating method, spray coating method, curtain coating method, dip coating method, air knife coating method, blade coating method, roll coating method, and hopper coating method. Particularly preferred among these coating methods are bar coating method, dip coating method and hopper coating method.

In the invention, the positive-working image-recording layer may comprise a surface active agent for improving coatability such as fluorine-based surface active agent as described in Japanese Patent Laid-Open No. 1987-170950. The amount of such a surface active agent to be incorporated in the positive-working image-recording layer is preferably from 0.01 to 1% by weight, more preferably from 0. 05 to 0.5% by weight based on the total solid content in the positive-working image-recording layer.

The lower layer coating solution which has been applied to the support and the image-recording layer coating solution which has been applied to the lower layer or the lower layer coating solution and the image-recording layer coating solution which have been sequentially applied to the support are each dried. Drying of these layers is carried out by the use of any known ordinary method. Examples of the drying method employable herein include convection heating method involving blowing of hot air onto the support thus coated, radiation heating method involving the mission of heat from lower and upper heating plates as described in Japanese Patent Laid-Open No. 1985-149871, and conduction heating method as described in Japanese Patent Laid-Open No.1985-21334 and Japanese Patent Laid-Open No. 1985-62778 which comprises allowing the support to come in contact with a roller through which a heat medium passes so that the support is dried by heat which has been conducted from the surface of the roller.

Referring to the developability of the printing plate precursor, when these drying conditions are severe, a tendency is given that the electrical conductivity of the developer at which an image can be formed rises (the developing properties deteriorate). On the contrary, when these drying conditions are mild, a tendency is given that the electrical conductivity of the developer at which an image can be formed lowers (the developing properties improve). The predetermination of desired drying conditions is carried out by adjusting conditions such as temperature of hot air, flow rate of hot air and temperature and material of contact heat medium.

In the case where an underlayer is provided on a support and an image-recording layer is provided on the underlayer, the image-recording layer coating solution is applied to the underlayer dried after the lowering of the temperature of the support to a predetermined value.

Examples of the method for lowering the temperature of the support include method which comprises blowing cold air onto the support, method which comprises allowing the support to come in contact with a roller through which a cold medium passes so that the support is cooled by the coldness conducted from the surface of the roller, method which comprises passing the support through a low temperature atmosphere such as water and method which comprises spraying a low boiling liquid onto the support so that the support is cooled by vaporization. Preferred among these methods is the method which comprises blowing cold air onto the support. The temperature of the cold air is preferably not higher than 50° C., more preferably not higher than 30+ C., particularly not higher than 10° C.

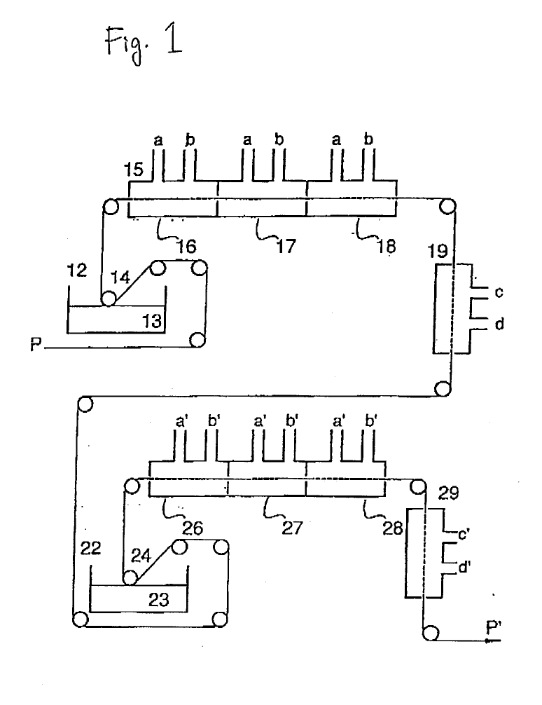

FIG. 1 illustrates an embodiment of the process for the preparation of the printing plate precursor of the invention. The embodiment shown in FIG. 1 comprises an underlayer coating/drying zone 1 and an image-recording layer coating/drying zone 2. In FIG. 1, a support P is fed into a coating device 12 of the lower layer coating zone 1 by roller conveyance. The coating device 12 is of dip coating type in the present embodiment. The support is coated with a coating solution 13 by a coating roller 14. The thickness of the coat layer is controlled by the conveyance rate, coating solution temperature, and solid concentration and viscosity of coating solution.

In the present embodiment, dip coating system is employed. However, any of the aforementioned coating methods such as hopper coating method may be employed. The support which has been coated with the lower layer coating solution is then conveyed to the lower layer drying zone 15. The drying zone of the present embodiment comprises three chambers, i.e., first section 16, second section 17 and third section 18. These chambers are each provided with a drying hot air inlet b and a drying hot air outlet a. The amount of air intake and discharge is controlled by an air intake and discharge controller provided in the vicinity of the hot air inlet of each intake duct. The flow rate at the inlet b and the outlet a of each chamber is adjusted such that no undesirable intake and discharge of air through the inlet and outlet of conveyed material drying chamber can occur. The flow rate and temperature of drying air are independently variable. The support coated with an underlayer coating solution which has been thus dried is conveyed into a cooling section 19 provided with a cold air blowing port d and a cold air outlet c where it is then once cooled to a predetermined temperature. The temperature of the cold air is preferably not higher than 50° C., more preferably not higher than 30° C., most preferably not higher than 10° C. The temperature of the support which has thus been cooled is not higher than 20° C., preferably from 15° C. to 17° C. Control is made such that the support carrying the lower layer is fed into the subsequent coating step while being kept at a predetermined temperature.

Subsequently the support carrying the lower layer is conveyed into a coating device 22 of image-recording layer coating zone 2 where it is then subjected to dip coating to form an image-recording layer in the present embodiment. The support is coated with a coating solution 23 by a coating roller 24. The thickness of the coat layer is controlled by the conveyance speed and temperature, solid concentration and viscosity of coating solution. In the present embodiment, the formation of the image-recording layer, too, is carried out by dip coating method. Any other coating method may be employed. The support which has been coated with the image-recording layer coating solution is then conveyed into an image-recording layer drying zone 25. The drying zone of the present embodiment comprises a first section 26, a second section 27 and a third section 28. These sections are each provided with a drying air inlet b and a drying air outlet a. The flow rate and temperature of drying air are independently variable. The support coated with a low layer coating solution which has been dried is fed into a cooling section 29 provided with a cold air flowing port d′ and a cold air discharge port c′ where it is then cooled to complete a printing plate precursor P′. The support side temperature of the completed printing plate precursor which has been supplied from the coating/drying device is not higher than 40° C., preferably from 22° C. to 35° C.

[Support]

As the support for the lithographic printing plate precursor to be used herein there may be used a dimensionally stable sheet-like material having required strength and durability. Examples of such a sheet-like material include paper, paper laminated with plastic (e.g., polyethylene, polypropylene, polystyrene), metal sheet (e.g., aluminum, zinc, copper), plastic film (e.g., cellulose diacetate, cellulose triacetate, cellulose propionate, cellulose butyrate, cellulose acetobutyrate, cellulose nitrate, polyethylene terephthalate, polyethylene, polystyrene, polypropylene, polycarbonate, polyvinyl acetal), and paper and plastic film laminated with such a metal or having such a metal vacuum-deposited thereon.

As the support for the lithographic printing plate precursor to be used herein there is preferably used a polyester film or aluminum plate. Particularly preferred among these materials is aluminum plate, which is dimensionally stable and relatively inexpensive. Preferred examples of the aluminum plate include a pure aluminum plate and an alloy plate mainly composed of aluminum containing a slight amount of foreign elements. Alternatively, a plastic film laminated with aluminum or having aluminum vacuum-deposited thereon may be used. Examples of the foreign elements to be incorporated in the aluminum alloy include silicon, iron, manganese, copper, magnesium, chromium, zinc, bismuth, nickel, and titanium. The content of the foreign elements. In the alloy is 10% by weight at largest. Aluminum which is particularly preferred in the invention is pure aluminum. However, since completely pure aluminum can be difficultly produced from the standpoint of refining technique, aluminum may contain a slight amount of foreign elements.

Thus, the composition of the aluminum plate which is applied to the invention is not limited. Aluminum plates having a composition which has heretofore been known and commonly used can be properly used. The thickness of the aluminum plate is from about 0.1 mm to 0.6 mm, preferably from 0.15 mm to 0.4 mm, particularly from 0.2 mm to 0.3 mm.

The aluminum plate is optionally subjected to degreasing with a surface active agent, an organic solvent or an alkaline aqueous solution for removing rolling oil from the surface thereof prior to roughening. The surface roughening of the aluminum plate is carried out by various methods. Examples of the roughening method include mechanical roughening method, method involving electrochemical dissolution and roughening of surface of aluminum plate, and method involving chemical selective dissolution of surface of aluminum plate. As the mechanical method there may be used any known method such as ball polishing method, brush polishing method, blast polishing method and buffing method. As the electrochemical roughening method there is used a method which comprises passing ac or do through the aluminum plate-dipped in hydrochloric acid or nitric acid electrolyte. As disclosed in Japanese Patent Laid-Open No. 11979-63902, a method involving the passage of ac and dc in combination may be employed. The aluminum plate thus roughened is subjected to alkali etching and neutralization as necessary, and then optionally subjected to an anodization for enhancing the surface water retention and abrasion resistance thereof. As the electrolyte to be used in the anodization of the aluminum plate there may be used any of various electrolytes capable of forming a porous oxide film. In general, sulfuric acid, phosphoric acid, oxalic acid, chromic acid or mixture thereof may be used. The concentration of such an electrolyte may be properly predetermined by the kind of the electrolyte.

The anodization conditions vary with electrolyte and thus herein comprises at least the aforementioned lower layer and positive-working image-recording layer provided on a support and may comprise a subbing layer provided interposed between the support and the lower layer.

As the subbing layer components there may be used various organic compounds. Examples of these organic compounds employable herein include those selected from the group consisting of phosphonic acids having amino group such as carboxyrethyl cellulose, dextrin gum arabic and 2-aminoethyl phosphonic acid, organic phosphonic acids such as phenyl phosphonic acid, naphthylphosphonic acid, alkyl phosphonic acid, glycerophoshonic acid, methylenediphosphonic acid and ethyienediphosphonic acid which may have substituents, organic phosphoric acids such as phenylphosphoric acid, naphthylphoshoric acid, alkylphosphoric acid and glycerophosphoric acid which may have substituents, organic phosphinic acids such as phenylphouphinic acid, naphthylphosphinic acid, alkylphosphinic acid and glycerophosphinic acid which may have substituents, amino acids such as glycine and β-alanine, and hydrochlorides of amine having hydroxyl group such as hydrochloride of triethanolamine. Two or more of these organic compounds may be used in admixture.

The subbing layer preferably contains at least one compound selected from the group consisting of organic polymer compounds having a structural unit represented by the following general formula.

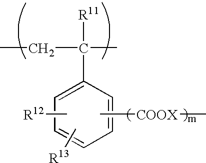

wherein R¹¹ represents a hydrogen atom, halogen atom or alkyl group, R¹² and R¹³ each independently represent a hydrogen atom, hydroxyl group, halogen atom, alkyl group, substituted alkyl group, aryl group, substituted aryl group, —OR¹⁴, —COOR¹⁵, —CONHR¹⁶, —COR¹⁷ or —CN or may be connected to each other to form a ring; R14 to R17 each independently represent an alkyl group or aryl group; X represents a hydrogen atom, metal atom or NR¹⁸R¹⁹R²⁰R²¹; R¹⁸ to R²¹ each independently represent a hydrogen atom, alkyl group, substituted alkyl group, aryl group or substituted aryl group; R¹⁸ and R¹⁹ may be connected to each other to form a ring; and m represents an integer of from 1 to 3.

The subbing layer can be provided by the following method. In other words, a method may be employed which comprises applying a solution of the aforementioned organic compound in water, an organic solvent such as methanol, ethanol and methyl ethyl ketone or a mixture thereof to an aluminum plate, and then drying the coated material to form an underlayer thereon. Another method may be employed which comprises dipping an aluminum plate in a solution of the aforementioned organic compound in water, an organic solvent such as methanol, ethanol and methyl ethyl ketone or a mixture thereof to cause the organic compound to be adsorbed by the aluminum plate, washing the aluminum plate with water or the like, and then drying the aluminum plate to form an underlayer thereon. In accordance with the former method, a solution of the aforementioned organic compound having a concentration of from 0.005. to 10% by weight can be applied by various methods. In the latter method, the concentration of the solution is from 0.01 to 20%t by weight, preferably from 0.05 to 5% by weight, the dipping temperature is from 20° C. to 90° C., preferably from 25° C. to 50° C., and the dipping time is from 0.1 seconds to 20 minutes, preferably from 2 seconds to 1 minute. The solution to be used in this method can be adjusted to a pH of from 1 to 12 with a basic material such as ammonia, trimethylamine and potassium hydroxide or an acidic material such as hydrochloric acid and phosphoric acid. The solution may comprise a yellow dye incorporated therein to improve the tone reproducibility of the image-recording material.

The coated amount of the subbing layer is preferably from 2 to 200 mg/m², more preferably from 5 to 100 mg/m². When the coated amount of the underlayer falls below 2 mg/m2, sufficient printing properties cannot be obtained. On the contrary, when the coated amount of the underlayer exceeds 200 mg/m2, similar troubles can occur.

[Plate Making/Printing]

In an ordinary embodiment, the positive-working printing plate precursors thus prepared are stacked with an interleaving paper provided interposed therebetween, packaged, shipped, transported, and then stored. In a typical embodiment of plate making and printing, a set of a laminate of interleaving paper and printing plate precursor is caught by an auto loader from which it is conveyed, and load and fixed at the plate-making position where the interleaving paper is then removed. However, the invention is not limited to this embodiment. The plate-making position is on the printing machine in the direct printing system.

The printing plate precursor from which the interleaving paper has been removed is then subjected to imagewise exposure and development.

The source of active rays to be used in the imagewise exposure is preferably a light source emitting light having a wavelength ranging from near infrared to infrared. The imagewise exposure is not necessarily of scanning type. In other words, the imagewise exposure may be of mask exposure type. However, scanning type exposure using a solid laser or semiconductor laser is preferred. The wavelength of light emitted is preferably from 760 nm to 1,080 nm.

The developer which can be used in the printing plate precursor of the invention is one having a pH value of from 9.0 to 14.0, preferably from 12.0 to 13.5. As the developer (the developer, including its replenisher, will be hereinafter referred to as “developer”) there may be used an alkaline aqueous solution which has heretofore been known. Examples of such an alkali include inorganic alkaline salts such as sodium silicate, potassium silicate, sodium tertiary phosphate, potassium tertiary phosphate, ammonium tertiary phosphate, sodium secondary phosphate, potassium secondary phosphate, ammonium secondary phosphate, sodium carbonate, potassium carbonate anmonium carbonate, sodium, hydrogencarbonate, potassium hydrogencarbonate, ammonium hydrogencarbonate, sodium borate, potassium borate, ammonium borate, sodium hydroxide, ammonium hydroxide, potassium hydroxide and lithium hydroxide. Further examples of such an alkali include organic alkaline agents such as momethylamine, dimethylamine, trimethylamine, monoethylamine, diethylamine, trimethylamine, monoisopropylamine, dimsopropylamine, triusopropylamine, n-butylamine, monoethanolamine, diethanolamine, triethanolamine, monoisopropanolamine, diisopropanolamine, ethylenimine, ethylenediamine and pyriddine. These alkaline aqueous solutions may be used singly or in combination of two or more thereof.

One of the developers which can exert the effect of the invention among the aforementioned alkaline aqueous solutions is an aqueous solution having a pH value of 12 or higher called “silicate developer” containing an alkali silicate or an alkali silicate obtained by mixing a base with a silicon compound as abase. Another preferred developer is a so-called “nonsilicate developer” containing a nonreducing sugar (organic compound having a buffering action) and a base free of alkali silicate.

In the former developer, the developing properties of the aqueous solution of silicate of alkaline metal can be adjusted by the ratio of silicon oxide SiO₂ as a silicate component to alkaline metal oxide M₂O (normally represented by [SiO₂]/[M₂O] molar ratio) and its concentration. For example, an aqueous solution of sodium silicate having SiO2/Na2O molar. ratio of from 1.0 to 1.5 (i.e., [SiO₂]/[Na₂O] molar ratio of from 1.0 to 1.5) and SiO₂ content of from 1 to 4% by weight as disclosed in Japanese Patent-Laid-Open No. 1979-62004 and an aqueous solution of silicate of alkaline metal having [SiO₂]/[M] ratio of from 0.5 to 0.75 (i.e., [SiO₂]/[M₂O] molar ratio of from 1.0 to 1.5), SiO₂ content of from 1 to 4% by weight and a potassium content of at least 20% based on gram atom of all alkaline metals present therein as disclosed in Japanese Patent Laid-Open No. 1982-7427 are preferably used.

It is more desirable that a so-called “non-silicate developer” containing a nonreducing sugar and a base free of alkali silicate be applied to the development of the lithographic printing plate precursor of the invention. When the lithographic printing plate precursor is subjected to development with this developer, the affinity of the photosensitive layer can be kept good without deteriorating the surface conditions of the photosensitive layer. A lithographic printing plate precursor normally has a narrow development latitude and thus is subject to great variation of width of line image with the pH value of the developer. However, the non-silicate developer contains a nonreducing sugar having a buffering effect of inhibiting the variation of pH and thus is of greater advantage than the developer containing silicate. Further, the nonreducing sugar can contaminate the conductivity or pH sensor for controlling the liquid activity more difficultly than silicate. In this respect, too, the non-silicate developer is advantageous. The non-silicate developer further exerts a remarkable effect of enhancing the discrimination between the image area and the non-image area. This is presumably because in the invention, the contact (penetration) with the developer essential for the maintenance of discrimination and film properties becomes mild, making it easy for the discrimination between the exposed area and the unexposed area to appear.

The aforementioned nonreducing sugar is a saccharide free of aldehyde group or ketone group which shows no reducing properties. Nonreducing sugars are classified into three groups, i.e., trehalose oligosaccharide comprising reducing groups connected to each other, glycoside comprising reducing group of saccharide and nonsaccharide connected to each other and sugar alcohol obtained by hydrogenating saccharide so that it is reduced. Any of these saccharides are preferably used in the invention. In the invention, nonreducing sugars described in Japanese Patent Laid-Open No. 1996-305039 are preferably used.

Examples of the aforementioned trehalose oligosaccharide include sucrose, and trehalose. Examples of the aforementioned glycoside include alkyl glycoside, phenol glycoside, and mustard oil glycoside. Examples of the aforementioned sugar alcohol include D, L-arabite, ribite, xylite, D, L-sorbite, D, L-mannitol, D, L-iditol, D, L-talitol, dulcite, and alodulcite. Further examples of sugar alcohol include maltitol obtained by hydrogenation of maltose, which is a disaccharide, and reduced material (reduced starch syrup) obtained by hydrogenation of oligosaccharide. Preferred among these nonreducing sugars are trehalose oligosaccharide and sugar alcohol. Particularly preferred among these nonreducing sugars are D-sorbite, sucrose, and reduced starch syrup because they have a buffering action within a proper pH range and are inexpensive.

These nonreducing sugars may be used singly or in combination of two or more thereof. The content of the aforementioned nonreducing sugar in the aforementioned non-silicate developer is preferably from 0.1 to 30% by weight, more preferably from 1 to 20% by weight. When the content of the aforementioned nonreducing sugar in the aforementioned non-silicate developer falls below 0.1% by weight, a tendency is given that no sufficient buffering action can be obtained on the contrary, when the content of the aforementioned nonreducing sugar in the aforementioned non-silicate developer exceeds 30% by weight, the aforementioned non-silicate developer can be difficultly concentrated and a tendency is given that the cost price thereof is raised.

Examples of the base to be used in combination with the aforementioned nonreducing sugar include alkaline agents which have heretofore been known, such as inorganic alkaline agent and organic alkaline agent. Examples of the inorganic alkaline agent employable herein include sodium hydroxide, potassium hydroxide, lithium hydroxide, trisodium phosphate, tripotassium phosphate, triammonium phosphate, disodium phosphate, dipotassiumphosphate, diammoniumphosphate, sodium carbonate, potassium carbonate, ammonium carbonate, sodium bydrogencarbonate, potassium hydrogencarbonate, ammonium hydrogencarbonate, sodium borate, potassium borate, and ammonium borate.

Examples of the organic alkaline agent employable herein include monoethylamine, dimethylamine, trimethylamine, monoethylamine, diethylamine, trimethylamine, monoisopropylamine, dimsopropylamine, triisopropylamine, n-butyl ne, monoethanolamine, diethanolamine, trioethanolamine, monoisopropanclamine, diisopropanolamine, ethylenimine, ethylenediamine, and pyridine.

The aforementioned bases may be used singly or in combination of two or more thereof. Preferred among these bases are sodium hydroxide and potassium hydroxide In the invention, as the aforementioned non-silicate developer there may be used one mainly composed of an alkaline metal salt of nonreducing sugar instead of combination of The aforementioned non-silicate developer may be used in combination with an alkaline buffer made of weak acid other than the aforementioned nonreducing sugar and strong base. The aforementioned weak acid preferably has an dissociation constant (pKa) of from 10.0 to 13.2. The aforementioned weak acid may be selected from those described in “Ionization Constants of Organic Acids in Aqueous Solution”, Pergnon Press.

Specific examples of the weak acid employable herein include alcohols such as 2,2,3,3-tetrafluoropropanol-1, trifluoroethanol and trichloroethanol, aldehydes such as pyridine-2-aldehyde and pyridine-4-aldehyde, compound having phenolic hydroxyl group such as salicylic acid, 3-hydroxy-2-naphthoic acid, catechol, gallic acid, sulfosalicylic acid, 3,4-dihydroxysulfonic acid, 3,4-dihydroxybenzoic acid,;hydroquinone, pyrogallol, o-cresol, in-cresol, p-cresol and resorcinol, oximes such as acetoxime, 2-hydroxybenzaldehyde oxime, dimethyl glyoxime, ethanediamide dioxime and acetopheone oxime, nucleic acid-related materials such as adenosine, inosine, guanine, cytosine, hypoxanthine and xanthine, diethylaminomethylsulfonic acid, benzimidazole and barbituric acid.

The aforementioned developer and replenisher may comprise various surface active agents or organic solvents incorporated therein as necessary for the purpose of accelerating or inhibiting the developing properties thereof, dispersing development scum or enhancing the affinity of the image area on the printing plate. Preferred examples of the aforementioned surface active agents include anionic, cationic, nonionic and amphoteric surface active agents. The aforementioned developer and its replenisher may further comprise hydroquinone, resorcin, reducing agent such as sodium salt and potassium salt of inorganic acid such, as sulfurous acid and hydrogen sulfurous acid, organic carboxylic acid, anti-foaming agent, water softener, etc. incorporated therein.

The image-forming material which has been subjected to development with the aforementioned developer and its replenisher is then subjected to post-treatment with washing water, a rinsing solution containing a surface active agent or the like, or a desensitizing solution containing gum arabic or starch derivative. The aforementioned image-forming material to be used as a printing plate may be subjected to these post-treatments in combination.

In recent years, in the plate-making and printing industry, automatic developing machines for printing have been widely used for rationalization and standardization of plate-making work. These automatic developing machines normally comprise a development zone and a post-treatment zone. In some detail, these automatic developing machines comprise a device for conveying printing plates and various processing tanks and spraying device. In operation, the printing plate which has been exposed is sprayed with various processing solutions pumped up through a spray nozzle while being horizontally conveyed so that it is subjected to development. A method has been recently known which comprises allowing the printing plate to be passed through a processing tank filled with a processing solution by the guidance of submerged guide rolls, etc. In these automatic development methods, the various processing solutions may be replenished with its replenishers depending on the required amount of the printing plate to be processed, operating time, etc. Alternatively, a so-called throwaway processing method involving the processing with substantially unused processing solutions may be employed.

The positive-working printing plate precursor according to the invention which has been subjected to imagewise exposure and development is then subjected to washing with water and/or rinsing and/or elimination of unnecessary image area (e.g., film edge mark on original film), if any, from gummed lithographic printing plate. The elimination of unnecessary image area is preferably accomplished by a method which comprises applying a deletion fluid as described in Japanese Patent Publication No. 1990-13293 to the unnecessary image area, allowing the coated area to stand for a predetermined period of time, and then washing the area with water. A method as disclosed in Japanese Patent Laid-Open No. 1984-174842 may be utilized which comprises irradiating the unnecessary image area with active rays led through an optical fiber as described in. Japanese Patent Laid-Open No. 1984-174842, and then developing the material thus irradiated.

The positive-working printing plate thus obtained may be optionally coated with a desensitizing gum before being subjected to printing step. In order to obtain a lithographic printing plate having a higher press life, burning may be effected. In order to subject the lithographic printing plate to burning, it is preferred that the lithographic printing plate be processed with a plate burning conditioner as disclosed in Japanese Patent Publication No. 1986-2518, Japanese Patent Publication No. 1980-28062, Japanese Patent Laid-Open No. 1987-31859, and Japanese Patent Laid-Open No. 1986-159655.

Examples of the burning method employable herein include a method involving the application of such a plate burning conditioner to the lithographic printing plate with a sponge or decreased cotton impregnated therewith, a method which comprises dipping the printing plate in a bat filled with a plate burning conditioner, and a method involving the application of a plate burning conditioner using an automatic coater. The uniformalization of the coated amount of the plate burning conditioner by a squeegee or squeegee roller gives better results.

In general, the coated amount of the plate burning conditioner is from 0.03 to 0.8 g/m² as calculated in terms of dried weight. The lithographic printing plate thus coated with a plate burning conditioner is optionally dried, and then heated to a high temperature using a burning processor (e.g., Type BP-1300 burning processor, commercially available from. Fuji Photo Film Co. Ltd.). In this case, the heating temperature and time are preferably from 180° C. to 300° C. and from 1 to 20 minutes, respectively, though depending on the kind of the components forming the image.

The lithographic printing plate thus burned may be properly subjected to processings which have heretofore been effected such as washing with water and gumming as necessary. However, in the case where a plate burning conditioner containing a water-soluble polymer compound or the like has been used, a so-called desensitization such as gumming may be omitted. The lithographic printing plate thus obtained is then mounted on an offset printing machine to provide a number of sheets of printed matters.

### EXAMPLES

The invention will be further described in the following examples, but the invention should not be construed as being limited thereto.

### Example 1

[Preparation of Substrate]

An aluminum plate (material: 1050) having a thickness o 0.3 mm was washed with trichlotoethylene so that it was degreased, grained on the surface thereof with a nylon brush and an aqueous suspension of 400-mesh pumice, and then thoroughly washed with water. The aluminum plate thus processed was dipped in a 45° C. 25% aqueous solution of sodium hydroxide for 9 seconds so that it was etched, washed with water, dipped in a 20% nitric acid for 20 seconds, and then washed with water. The etched amount on the grained surface was about 3 g/m². Subsequently, the aluminum plate was subjected to electrolysis in a 7% sulfuric acid as an electrolyte at a current density of 15 A/dm² to form a dc anodized film to a thickness of 3 g/m², washed with water, dried, processed with a 2.5 weight-% aqueous solution of sodium silicate at 30° C. for 10 seconds, coated with the following undercoating solution, and then dried on the coat layer at 80° C. for 15 seconds to obtain a substrate. The coated amount of the coat layer thus dried was 15 mg/m².

| [Subbing solution] | | |
|---|---|---|
| *Polymer compound described below | 0.3 | g |
| *Methanol | 100 | g |
| *Water | 1 | g |

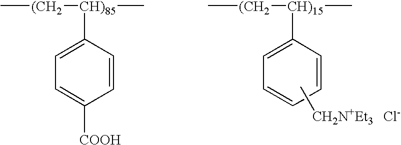

Molecular weight: 28,000

[Formation of Positive-Working Image-Recording Layer]

The present example was conducted in the same manner as shown in FIG. 1 except that the dip coating method to be conducted in the coating zone of the printing plate precursor coating/drying device was changed to wire bar coating method. In the coating device 12 shown in FIG. 1, an underlayer solution having the following composition was applied to the substrate to a thickness of 1.0 g/m² by means of a wire bar capable of coating in a wet amount of 19 cc/m². The substrate thus coated was conveyed into the drying device 15 where it was then dried by a continuous conveyance dryer (drying oven) of convection heating system using a hot air. The first section 16 was arranged such that the material is dried at an inter air temperature of 140° C. for 10 seconds, the second section 17 was arranged such that the material is dried at an inter air temperature of 160° C. for 20 seconds, and the third section 18 was arranged such that the material is dried at an inter air temperature of 160° C. for 40 seconds.

The support with underlayer which had passed through the drying device was conveyed into the cooling section 19 where it was then cooled to a temperature of 35° C. at the inlet of the second coating device 22 attained by adjusting the temperature and flow rate of cooling air by the air intake c and the air outlet d. Subsequently, in the second coating device 22, an image-recording layer coating solution having the following composition was applied to the underlayer in a total amount of 1.2 g/m² by means of a wire bar capable of coating in a wet amount of 7.5 cc/m². The printing plate precursor sample thus coated was conveyed into the drying device where it was then dried at an inter air temperature of 120° C. for 8 seconds at the fourth section 26, dried at an inter air temperature of 130° C. for 10 seconds at the fifth section 27 and dried at an inter air temperature of 150° C. for 20 seconds at the sixth section 28. Subsequently, the sample was cooled at the cooling section 29 to obtain a positive-working lithographic printing plate precursor sample P′.

| | | |
|---|---|---|
| [Underlayer coating solution] | | |
| *Binder of N-(4-aminosulphenyl)methacrylamide/ | 2.133 | g |
| acrylonitrile/methyl methacrylate | | |
| (36/34/30: weight-average molecular weight: 5,000) | | |
| *Cyanine dye A (having the following structure) | 0.109 | g |
| *4,4′-Bishydroxyphenylsulfone | 0.126 | g |
| *Tetrahydrophthalic anhydride | 0.190 | g |
| *p-Toluenesulfonic acid | 0.008 | g |
| *Ethyl violet having its counter anion changed | 0.100 | g |
| to 6-hydroxynaphthalenesulfonic acid | | |
| *3-Methoxy-4-diazodiphenylamine | 0.03 | g |
| hexafluorophosphate (heat-decomposable compound) | | |
| *Fluorine-based surface active agent (Megafac | 0.035 | g |
| F176, produced by DAINIPPON INK AND CHEMICALS, | | |
| INCORPORATED) | | |
| *Methyl ethyl ketone | 26.6 | g |
| *1-Methoxy-2-propanol | 13.6 | g |
| *γ-Butyrolactone | 13.8 | g |
| [Image-recording layer (upper layer) coating solution] | | |
| *m, p-Cresol novolak (PR54046, produced by | 0.348 | g |
| Sumitomo Dures Co., Ltd.) | | |
| *Cyanine dye A (having the following structure) | 0.0192 | g |
| *Tetraethylammonium bromide | 0.030 | g |
| *Fluorine-based surface active agent (Megaface | 0.035 | g |
| F176J, produced by DAINIPPON INK AND CHEMICALS, | | |
| INCORPORATED) | | |
| *Solvent having the composition set forth in Amount set | | |

| | |
|---|---|
| Table 1 | forth Table 1 |

Cyanine dye A

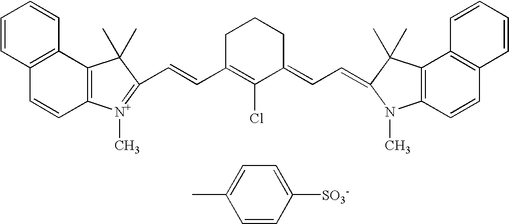

TABLE 1

| | | | Electrical | | |
|---|---|---|---|---|---|
| | Composition of solvent | Dissolution of | conductivity at | | |
| | for upper layer coating | underlayer | which film | Scratch | |
| | solution | component (%) | reduction occurs | resistance (g) | Press life |
| Example 1 | Methyl ethyl ketone | 13 | 53 | 15 | 600,000 |
| Example 2 | 1-Methoxypropanol | 11 | 53 | 17 | 650,000 |
| Example 3 | Cyolohexanone | 13 | 51 | 13 | 550,000 |
| Example 4 | Methyl ethyl | 13 | 51 | 13 | 530,000 |
| | ketone/methanol = 5/1 | | | | |
| Example 5 | Methanol | 11 | 53 | 15 | 570,000 |
| Comparative | γ-Butyrolactone | 98 | 45 | 3 | 100,000 |
| Example 1 | | | | | |
| Comparative | Methyl ethyl | 50 | 45 | 5 | 130,000 |
| Example 2 | ketone/γ-butyrolactone = | | | | |
| | 10/1 | | | | |
| Comparative | Methyl ethyl | 26 | 47 | 5 | 150,000 |
| Example 3 | ketone/1-methoxypropano | | | | |
| | 1 = 1/1 | | | | |

[Evaluation of Lithographic Printing Plate Precursor]

The various positive-working printing plate precursor samples thus obtained were each developed with a developer D-1 (produced by Fuji Photo Film Co., Ltd.) in an ordinary manner. These developed samples were then evaluated for solubility of underlayer component, mixing of underlayer component with upper layer coating solution, sensitivity, electrical conductivity at which film reduction occurs and scratch resistance. These evaluation tests were made on the samples which had been stored at 25° C. for 7 days after coating. Al the results are set forth in Table 1.

[Solubility of Underlayer Component]

A sample having only an underlayer formed thereon was dipped in the solvent for the upper layer coating solution for. 30 seconds, washed with water, and then dried. The solubility of underlayer component was then calculated from the drop of weight.

[Sensitivity]

The lithographic printing plate precursor thus obtained was imagewise exposed to test pattern with its exposure energy varied by means of Trend setter (produced by Creo Co., Ltd.). Thereafter, the lithographic printing plate precursor thus exposed was then developed with a developer DT-1 (diluted to have an electrical conductivity of 45 mS/cm) produced by Fuji Photo Film Co., Ltd. For the determination of sensitivity, the exposure energy at which the non-image area can be developed with this developer was measured. The smaller this value is, the higher is the sensitivity thus evaluated.

[Electrical Conductivity at which Film Reduction Occurs]

The “electrical conductivity at which the exposed area on the recording layer undergoes film reduction” was measured in the manner as previously described. In some detail, several kinds of developers having different electrical conductivities were prepared. These developers were each measured for electrical conductivity. The aforementioned lithographic printing plate which had been imagewise exposed was then developed with the aforementioned various developers. The lithographic printing plate was then measured for image density on the unexposed area (image area)by means of a Type D196 GRETAC reflection densitometer (produced by Gretagsacbeth Inc.). The lithographic printing plate which had been developed with a developer having the highest electrical conductivity at which the exposed area (non-image area) is not dissolved was then measured for image density. The electrical conductivity of the developer with which an image area having an image density of 0.06 lower than this image density had been formed was then measured. This electrical conductivity was defined to be “electrical conductivity at which film reduction occurs” according to the invention.

[Scratch Resistance]

Using a scratch tester produced by BEIDON CO., LTD., the lithographic printing plate precursors 1 to 8 obtained were each scratched on the plate with a load imposed on sapphire (1.0 mm). The lithographic printing plate thus scratched was then developed with a Type DT-1 developer (diluted to have an electrical conductivity of 45 mS/cm) produced by Fuji Photo Film Co., Ltd. Thus, the load at which scratch can be visually recognized was then determined. The greater the load thus measured is, the better is the scratch resistance thus evaluated.

As can be seen in Table 1, the printing plate precursors comprising the solvent defined herein as a solvent for image-recording layer coating solution (Examples 1 to 5) have a less upper layer (image-recording layer); dissolved in and mixed with the underlayer than. Comparative Examples 1 to 3, which comprise a solvent falling outside the definition of the invention. Thus, Examples 1 to 5 are excellent in the discrimination between image area and non-image area, which is reflected by the electrical conductivity at which film reduction occurs, as well as in scratch resistance and press life.

In accordance with the preparation process of the invention, a positive-working printing plate precursor for infrared laser can be obtained which exhibits an excellent discrimination between image area and non-image area and scratch resistance and a remarkably improved press life. Further, in accordance with the preparation process of the invention, the change of the composition of the image-recording layer coating solution can be inhibited over an extended period of time, making it possible to continuously prepare a printing plate precursor invariably over an extended period of time.

While the invention has been described in detail and with reference to specific embodiments thereof, it will be apparent to one skilled in the art that various changes and modifications can be made therein without departing from the spirit and scope thereof.

The entire disclosure of each and every foreign patent application from which the benefit of foreign priority has been claimed in the present application is incorporated herein by reference, as if fully set forth.

What is claimed is:

1. A process for producing a multi-layer printing plate precursor, the multi-layer printing plate precursor comprising a support, an underlayer and an image-recording layer, in this order, in which the underlayer comprises a water-insoluble and alkali-soluble resin, the image-recording layer comprises a water-insoluble and alkali-soluble resin and an infrared absorbent, and the image-recording layer increases the solubility in an alkaline aqueous solution upon irradiation with infrared laser beam,
wherein the process comprises forming the image-recording layer with the use of a solvent that doesn't dissolvent component of the underlayer in an amount of 20% by weight or more as a solvent for image-recording layer coating solution.

2. The process for producing a multi-layer printing plate precursor as described in claim 1, wherein the solvent for image-recording layer coating solution is a solvent that doesn't dissolve a component of the underlayer in an amount of 13% by weight or more.

3. The process for producing a multi-layer printing plate precursor as described in claim 1, wherein the solvent for image-recording layer coating solution is a solvent that doesn't dissolve a component of the underlayer in an amount of 10% by weight or more.

4. The process for producing a multi-layer printing plate precursor as described in claim 1, wherein the solvent for image-recording layer coating solution is at least one solvent selected from the group consisting of ethylene dichloride, cyclohexanone, methyl ethyl ketone, methanol, ethanol, propanol, ethylene glycol monomethyl ether, 1-methoxy-2-propanol, 2-methoxy ethyl acetate, 1-methoxy-2-propyl acetate, dimethoxyethane, methyl lactate, ethyl lactate, N,N-dimethyl acetamide, N,N-dimethyl formamide, tetramethylurea, N-methylpyrrolidone, dimethyl sulfoxide, sulfolane, γ-butyrolactone and toluene.

5. The process for producing a multi-layer printing plate precursor as described in claim 1, wherein the solvent for image-recording layer coating solution is at least one solvent selected from the group consisting of cyclohexanone, methyl ethyl ketone, methanol, ethanol, propanol and 1-methoxy-2-propanol.

6. The process for producing a multi-layer printing plate precursor as described in claim 1, comprises:
coating a underlayer coating solution on the support; and
coating the image-recording layer solution on the under layer.

7. The process for producing a multi-layer printing plate precursor as described in claim 1, comprises:
coating a underlayer coating solution on the support;
drying the coated underlayer; and
coating the image-recording layer solution on the under layer.

8. The process for producing a multi-layer printing plate precursor as described in claim 1, wherein the a water-insoluble and alkali-soluble resin in the underlayer includes at least one of a water-insoluble and alkali-soluble polymer having a sulfonamide group and a water-insoluble and alkali-soluble polymer having an active imide group.

9. The process for producing a multi-layer printing plate precursor as described in claim 1, wherein the image-recording layer further comprises a heat-decomposable material that, when thermally undecomposed, substantially lowers the solubility of the water-insoluble and alkali-soluble resin.

10. The process for producing a multi-layer printing plate precursor as described in claim 9, wherein the heat-decomposable material is an onium salt.

11. The process for producing a multi-layer printing plate precursor as described in claim 10, wherein the onium salt is a diazonium salt.
